(19) United States
(12) Patent Application Publication
(10) Pub. No.: US 2019/0280652 A1
(43) Pub. Date: Sep. 12, 2019

(54) LOW NOISE SENSOR AMPLIFIERS AND TRANS-IMPEDANCE AMPLIFIERS USING COMPLEMENTARY PAIR OF CURRENT INJECTION FIELD-EFFECT TRANSISTOR DEVICES

(71) Applicant: Circuit Seed, LLC, Newport Beach, CA (US)

(72) Inventors: Susan Marya Schober, Newport Beach, CA (US); Robert C. Schober, Huntington Beach, CA (US); Terrence R. Hudrlik, Blaine, MN (US)

(21) Appl. No.: 16/463,711

(22) PCT Filed: Nov. 24, 2017
(86) PCT No.: PCT/US2017/063180

§ 371 Date: May 23, 2019

Related U.S. Application Data
(60) Provisional application No. 62/425,642, filed on Nov. 23, 2016.

(51) Int. Cl. H03F 1/26; H03F 1/08; H03F 3/45

(52) U.S. Cl. CPC H03F 1/26; H03F 1/086; H03F 2200/294; H03F 3/45179; H03F 3/45475

(57) ABSTRACT

This invention relates to low noise sensor amplifiers and trans-impedance amplifiers using a complementary pair of current injection field effect transistor (iFET) devices (CiFET). CiFET includes a N-type current field-effect transistor (NiFET) and a P-type current field-effect transistor (PiFET), each of the NiFET and PiFET has a source, a drain, a gate, and a diffusion (current injection) terminal (iPort). Each iFET also has a source channel with a width and a length between the source and diffusion terminal, and drain channel with a width and a length between the drain and the diffusion terminal. A trans-impedance of the CiFET device is adjusted by a ratio of width/length of source channel over width/length of drain channel of the iFET and supply power voltage. In one configuration, the gate terminals of the NiFET and PiFET are connected together to form a common gate. In another configuration that common gate is configured as a voltage input for a high input impedance mode. Output voltage swings around a common mode voltage.

### CROSS-REFERENCE TO RELATED APPLICATIONS

This application claims priority to U.S. Provisional Application No. 62/425,642, filed on Nov. 23, 2016, the content of which is incorporated herein by reference in its entirety.

### FIELD OF THE INVENTION

This invention relates to low noise sensor amplifiers and trans-impedance amplifiers using complementary pair of current injection field effect transistor devices.

### BACKGROUND OF THE INVENTION

All signal sources function by projecting energy into its immediate surrounds. If the system under consideration is an electronic circuit, most of the projected power travels through its wires, and some may radiate. If the system under consideration is a volume conductor the energy projected into it will rapidly move throughout that medium such as an antenna projecting radio signal into the space. If the system is mechanical, the energy flux may move in waves from one point to another. No matter what the system electronic, fluid or wind, the signal source projects energy into its surround and that energy propagates away from the source; the process is always the same.

As the signal energy propagates through the volume media, its progress and magnitude are characterized by the Pointing Vector. The goal of any form of sensing is to intercept and register this energy flow, which is the sensed signal. The purpose of any sensing system is to intercept and collect some of that energy in the most effective form possible, by effective one means both as efficiently as possible and by excluding as much outside sources of energy as possible. Sensing the energy of this energy flux efficiently and with as little added system noise is the ultimate goal of any sensing in any type of system. The systems performance is judged on the merits of its ability to do so.

One way to do this is to have the receiver absorb as much of the signal energy flux as possible. An amplifier's performance is often judged by factors including quiescent power, noise the amplifier injects, overall noise of the implemented circuit and compatibility with up and downstream systems.

One way to design a sensor front end amplifier system is to adjust the sensing to focus on the power that the signal source is able to project into the sensed local region where the sensor is located. In FIG. 1a, a circuit 10a shows that such a Thevenin voltage signal source is driving an adjustable resistance load R_{LOAD}. The magnitude of the voltage source is V_{OC}, which is short for voltage open circuit, and means that if no current or power is drawn from this system, the open circuit voltage V_{OC} presents between at the terminals A and B. FIG. 1a of the black box 10b that contains this voltage signal source. In FIG. 1b, a circuit 11a shows that the signal source is drawn in a current source form to the black box 11b. In the current source form, the current source has a value equal to the current that will flow in the attached circuit if the R_{LOAD} resistance is set to a value of 0 ohms. This is the maximum amount of current flow that is possible. The value of this maximum current is called I_{SS} or the current short circuit. The internal impedance of such a signal source is called the internal Thevenin resistance R_{TH}. This internal Thevenin resistance R_{TH} is the ratio of voltage open circuit to current short circuit. The internal resistance of a power source is the reason why your car cranks slower in cold weather. The cold increases the car batteries internal resistance while leaving the V_{OC}, the open circuit voltage unchanged.

There is a long-felt need for extending or bringing forth new capabilities in all these areas for sensors and sensor amplifiers. Several embodiments of the present invention will be detailed later to show a traditional Wheatstone bridge application and a new circuit configuration that can be used to sense from an implanted electrode or sense from an RF antenna while concurrently transmitting.

### SUMMARY OF INVENTION

The present invention relates to circuits built out of a novel and inventive compound device structure. In particular, the present invention relates to low noise sensor amplifiers and trans-impedance amplifiers using complementary pair of current field effect transistor devices.

According to one aspect of the present invention, it provides an apparatus having a complementary pair of a N-type current field-effect transistor (NiFET) and a P-type current field-effect transistor (PiFET). Each of NiFET and PiFET comprises a source terminal, a drain terminal, a gate terminal, and a diffusion terminal (iPort) of a corresponding conductivity type of the each of the PiFET and the NiFET, defining a source channel with a width and a length between the source terminal and the diffusion terminal, and a drain channel with a width and a length between the drain terminal and the diffusion terminal, the diffusion terminal causes changes in the diffused charge density throughout the source and drain channels, and the gate terminal is capacitively coupled to the source channel and the drain channel. The gate terminal of the PiFET and the gate terminal of the NiFET are connected together to form a common gate terminal for referring to a common mode voltage, and the drain terminals of the NiFET and the PiFET are connected together to form an output. The diffusion terminal and the source terminal of one of the NiFET or PiFET are connected in series with a signal source having a source impedance. The source channel of one of the NiFET and PiFET having an input impedance for matching with the source impedance, the input impedance is adjusting by a ratio of the width to the length of the source channel over the width to the length of the drain channel of the one of the PiFET and the NiFET. The input impedance may further be adjusted by a value of a supply power voltage. The ratio is adjusted to have the input impedance to be a low value for allowing to measure a short circuit current or to be a high value for allowing to measure a voltage source.

According to another aspect of the present invention, it provides a transimpedance amplifier comprising a complementary pair of a N-type current field-effect transistor (NiFET) and a P-type current field-effect transistor (PiFET), each of NiFET and PiFET comprises a source terminal, a drain terminal, a gate terminal, and a diffusion terminal (iPort) of a corresponding conductivity type of the each of the PiFET and the NiFET, which are defining a source channel with a width and a length between the source terminal and the diffusion terminal, and a drain channel with a width and a length between the drain terminal and the diffusion terminal, the diffusion terminal causes changes in the diffused charge density throughout the source and drain channels, and the gate terminal is capacitively coupled to the source channel and the drain channel. The gate terminal of the PiFET and the gate terminal of the NiFET are connected together to form a common gate terminal, and the drain terminals of the NiFET and the PiFET are connected together to form an output. The diffusion terminal of the NiFET and the diffusion terminal of the PiFET are for receiving input current simultaneously or seperately, in which the source channel of the NiFET and the source channel of the PiFET have an input impedance for matching with the source impedance. The input impedance for the NiFET is adjusting by a ratio of the width to the length of the source channel over the width to the length of the drain channel of the NiFET. Likewise, the input impedance for the PiFET is adjusting by a ratio of the width to the length of the source channel over the width to the length of the drain channel of the PiFET. The common gate terminal receives, simultaneously or separately from NiFET and/or PiFET, voltage signal in a high impedance mode.

According to yet another aspect of the present invention, it provides a differential transimpedance amplifier, having a first complementary pair of a first n-type current field-effect transistor (NiFET) and a first p-type current field-effect transistor (PiFET) and a second complementary pair of a second NiFET and a second PiFET. For each of the NiFETs and PiFETs, it has a source terminal, a drain terminal, a gate terminal, and a diffusion terminal (iPort) of a corresponding conductivity type of the each of the PiFET and NiFET, defining a source channel between the source terminal and the diffusion terminal, and a drain channel between the drain terminal and the diffusion terminal, the diffusion terminal causes changes in the diffused charge density throughout the source and drain channels, and the gate terminal is capacitively coupled to the source channel and the drain channel. The gate terminal of the PiFET and the gate terminal of the NiFET are connected together to form a common gate terminal for each complimentary pair, the source terminal of the NiFET of each pair is connected to negative power supply and the source terminal of the PiFET of the each pair is connected to positive power supply, and drain terminals of the NiFET and the PiFET are connected together to form an output. The common gate of the first complimentary pair and the common gate of the second complementary pair are connected with the output of the second complementary pair to for generating an output voltage swings about a common mode voltage. The diffusion terminal of the first NiFET receives a positive input current and the diffusion terminal of the second NiFET receives a negative input current. The output of the first complementary pair forms a positive voltage output and the output of the second complementary pair forms a negative voltage output of the trans-impedance amplifier.

### BRIEF DESCRIPTION OF DRAWINGS

FIG. 1a illustrates a diagram showing a conceptual voltage signal sensing model;

FIG. 1b illustrates a diagram showing a conceptual current signal sensor model;

FIG. 1c illustrates a graph showing relationship among current short circuit (I_{SS}), product of the voltage across and the current through the load resistance (P_{RL}), and voltage open circuit (V_{OC}) over adjustable load resistance (R_{LOAD} or R_{L});

FIG. 2a illustrates three-dimensional perspective view of a MOS field-effect transistor (or iFET) with a new mid-channel bi-directional current port (iPort) of a preferred embodiment of the present invention;

FIG. 2b illustrates a cross-section view of the iFET with visualized channel charge distribution;

FIG. 2c illustrates a complementary pair of iFET (CiFET) compound device;

FIGS. 3a-1 and 3a-2 illustrate an exemplary operational temperature performance range of CiFET;

FIG. 3b illustrates a linearity of CiFET over many decades of current signal input range;

FIGS. 3c and 3d illustrate harmonic distortion in the Fourier transform harmonic analysis on CiFET;

FIG. 3e illustrates a conceptual CiFET showing iFET ratio and common mode ratio (or cmRatio) based on a length and a width of source channel and a length and a width of drain channel of PiFET/NiFET;

FIG. 4a illustrates a diagram of a voltage signal sensor model using a CiFET;

FIG. 4b illustrates a diagram of a current signal sensor model using a CiFET;

FIG. 4c illustrates a diagram of a high-input impedance signal sensor model using a CiFET;

FIG. 4d illustrates a circuit diagram of Wheatstone bridge configuration using a dual CiFET;

FIG. 5a illustrates a diagram of a differential CiFET trans-impedance amplifier (dCiTIA) using CiFETs;

FIG. 5b shows a symbol diagram of dCiTIA;

FIG. 5c shows an exemplary diagram for a RF transceiver using dCiTIA;

FIG. 6 shows an exemplary diagram for a sensory circuit using voltage, current and voltage mode types of measurements based on a CiFET;

FIG. 7a shows a low frequency small signal model for a prior art MOS transistor;

FIG. 7b illustrates a conductance modeling of CiFET;

FIG. 8 illustrates an exemplary gain performance over power supply voltage range of CiFET;

FIG. 9a illustrates an exemplary trans-impedance amplifier (or TIA) using CiFETs;

FIG. 9b illustrates another exemplary TIA using CiFETs; and

FIG. 9c illustrates various impedance performance over range of iFET Ratio.

### DETAILED DESCRIPTION OF THE INVENTION

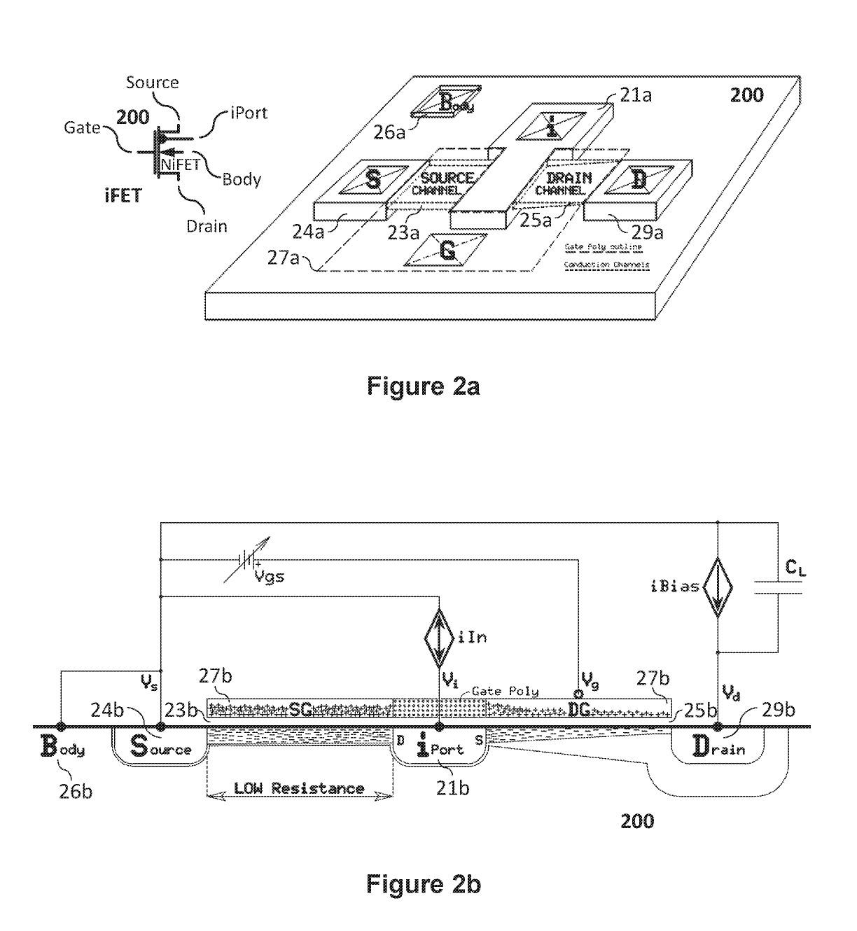

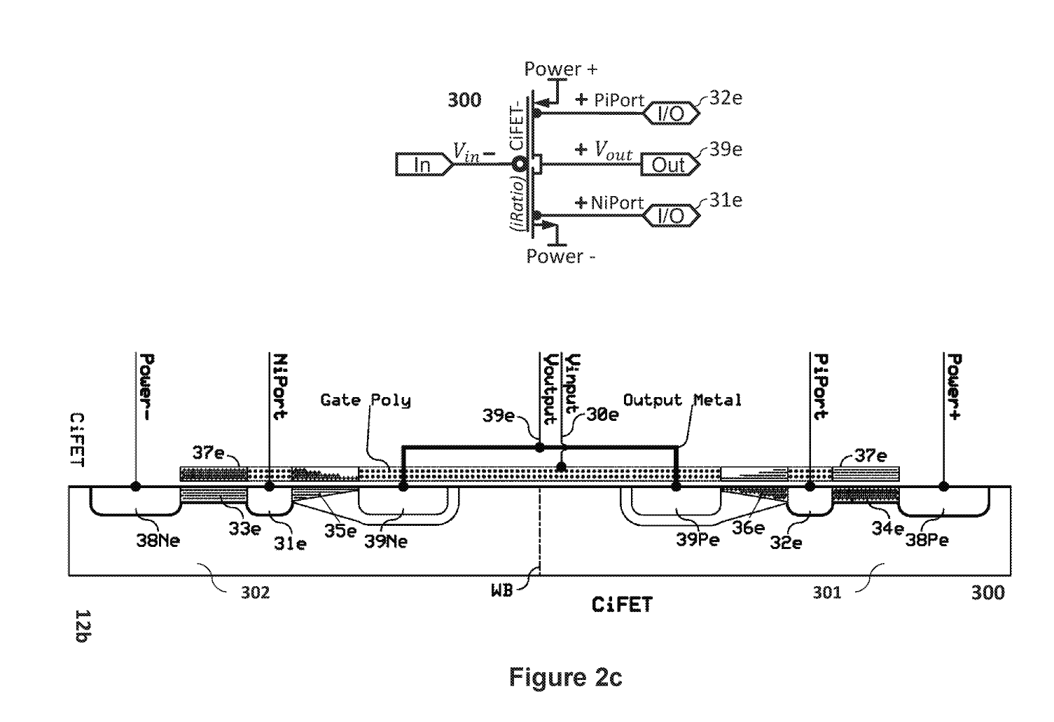

Referring to FIGS. 2a and 2b, according to a preferred embodiment of the present invention, it provides a current injection Field Effect Transistor (or iFET) 200, which is an enhanced MOSFET and is comprised of substrate 26a or 26b, source terminal 24a or 24b. and drain terminal 29a or 29b, defining there between two channels 23a and 25a, or 23b and 25b on the substrate 26a or 26b, respectively, typically the first (source channel 23a, or 23b) is connected to the power supply (not shown) while the second (drain channel 25a, or 25b) connects to the load (not shown). The substrate 26a or 26b is N- or P-type. The two channels, source and drain channels 23a and 25a, or 23b and 25b, respectively, are connected to each other as shown in FIGS. 2a, and 2b, at the iPort control terminal 21a or 21b, and the channels 23a and 25a, or 23b and 25b, share a common gate control terminal 27a or 27b, respectively. This configuration means that the iFET structure 200 has more than one control input terminal.

The gate control terminal 27a or 27b operates like a conventional MOSFET insulated gate, with its high input impedance and a characteristic Trans-conductance (gm) transfer function. Typical values of (gm) for a small-signal iFET are 1 to 30 millisiemens (1 millisiemen=1/1K-ohm) each, a measure of Trans-conductance.

FIG. 2c is a cross-section view of complementary pair of iFET (or CiFET) 300, which comprises P-type iFET (or PiFET) 301 and N-type iFET (or NiFET) 302, comprising input terminal 30e connected to both the gate control terminal 37e of PiFET 301 and NiFET 302, function as the common gate terminal 30e. CiFET 300 receives power, Power − and Power +, where Power − is connected to the source terminal of NiFET 302 and Power + is connected to the source terminal of PiFET 301. Each of PiFET 301 and NiFET 302 comprises iPort control terminals (31e and 32e) for receiving injection current. The drain terminal of PiFET 301 and NiFET 302 are combined to provide output 39e.

In the CiFET 300, PiFET 301 and NiFET 302 are laid out on the substrate (or body B+ and B− respectively) like a mirror image along well border WB shown therein; PiFET 301 comprises source terminal 38Pe, drain terminal 39Pe, and diffusion terminal or iPort control terminal/diffusion region 32e, defining source+channel 34e between the source terminal 38Pe and the iPort control terminal/Pi diffusion region 32e, and drain channel 36e between the drain terminal 39Pe and the iPort control terminal/Pi diffusion region 32e. NiFET 302 comprises source terminal 38Ne, drain terminal 39Ne, and iPort control terminal/Pi diffusion region 31e, defining source channel 33e between the source terminal 38Ne and the iPort control terminal/Ni diffusion region 31e, and drain channel 35e between the drain terminal 39Ne and the iPort control terminal/Ni diffusion region 31e. CiFET 300 further comprises a common gate terminal 30e over source+channel 34e, drain+channel 36e, source − channel 33e and drain − channel 35e. Accordingly, the common gate terminal 30e is capacitively coupled to the channels 34e, 36e, 35e, and 33e.

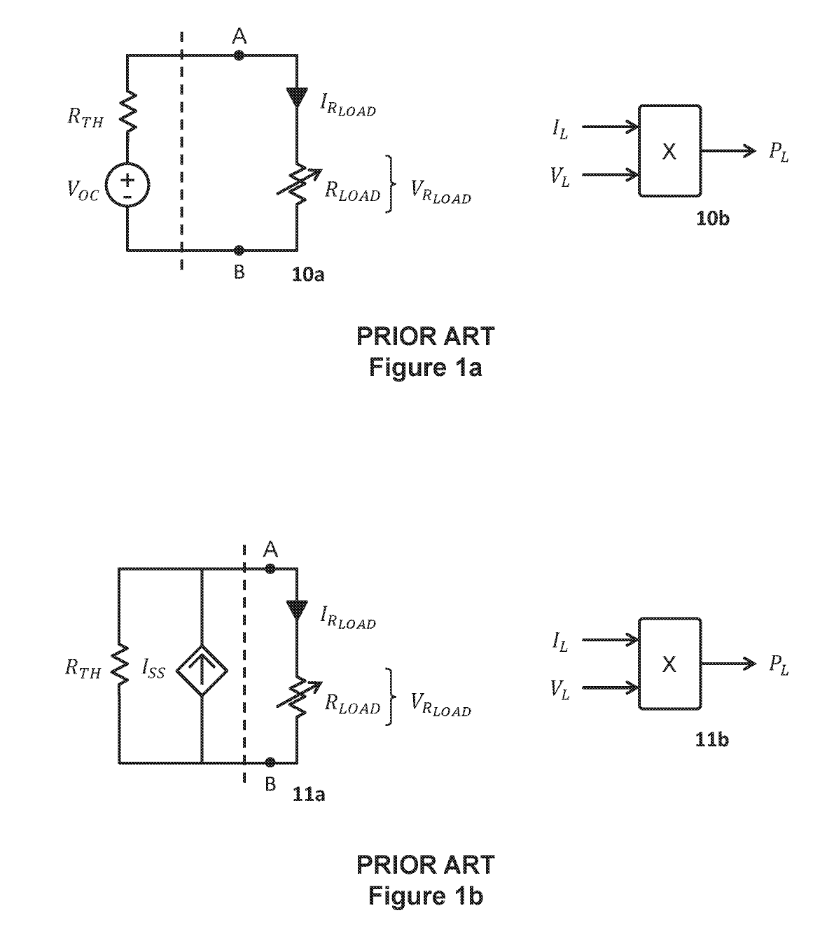

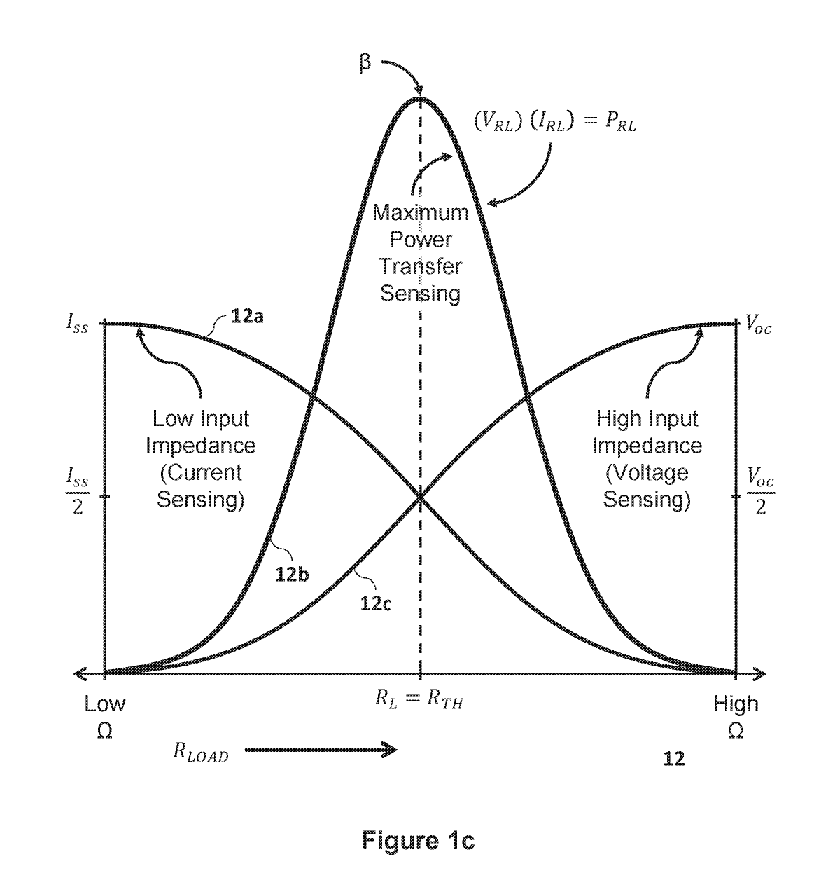

Referring back to FIG. 1a or 1b, to measure, track, monitor or record the source, the measurement circuit needs to have access to at least two leads from the source system. Consider what happens as an adjustable resistance R_{LOAD} is connected to the two leads and further the value resistance is adjusted across a wide range while the current though it and the voltage across it is monitored. The plot of these voltages and current through and across the load resistor R_{LOAD} is shown in FIG. 1c. In this plot, the current through the load resistance is shown to be maximum, I_{SS}, when the load resistance value is zero (low input impedance). In a similar fashion the open circuit voltage occurs as the load resistance value is far beyond the value of the internal Thevenin source resistance value (R_{TH}) or essentially an infinite load resistance (high input impedance). Also plotted, P_{RL} is the product of the voltage across and the current through the load resistance R_{L}. This is the power that the signal source is able to pass into the load resistor R_{LOAD}. This load adjusted passed power P_{RL} engages the signal power source and can in cases help separate signals coming from equal open circuit voltage sources. The signal sources are distinguished from each other by their respective delivered power. When sensing inter-cardiac signals, for example, this technique helps maximize the signal component expression of the local heart depolarization from a more distant muscle contraction. This type of measurement technique increases the signal to noise ratio of the desired signal by diminishing the received signal from the more distant signal sources. The signal to noise ratio is inherently improved by using this technique. The fidelity of the sensed wideband transduced signal is much improved compared to using a bandwidth limiting technique that mutes all signals outside the expected signal frequency range. The new lower noise floor and wideband signal fidelity promises to uncover new features in the unobstructed transduced signal.

The CiFET family either as a standalone device or in the form of a pair of CiFETs called a transimpedance amplifier (or TIA) is able to interface with sensors and signal sources optimally by tuning in on any off these three characteristics, 1) a voltage source, 2) a current source or 3) a source that can deliver power to the load resistance. The CiFET node input is further able to have its small signal input impedance adjusted so as to maximize the power transfer from a source or allow the small signal input resistance to be adjusted so as to present a high input impedance to a voltage source or an extremely low input impedance to a current source. The CiFET device as a sense amp can be all these things to a signal source whereas with operational amplifier based sensor interfacing several operational amplifiers and external components may be required to achieve the same end.

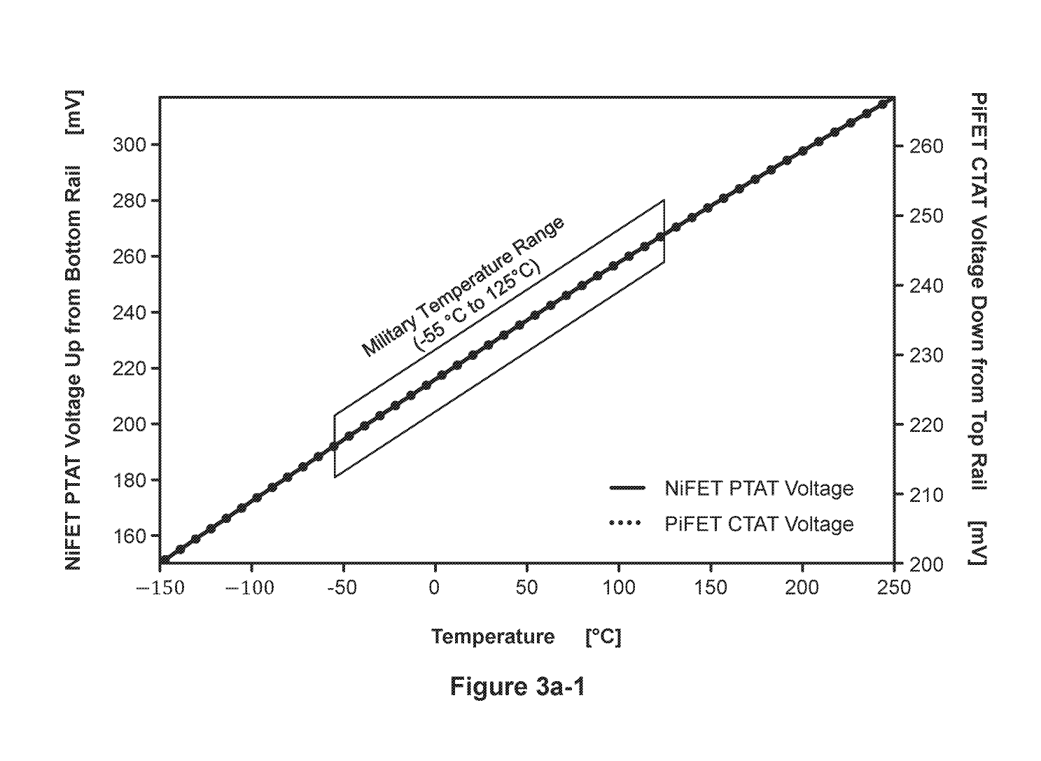

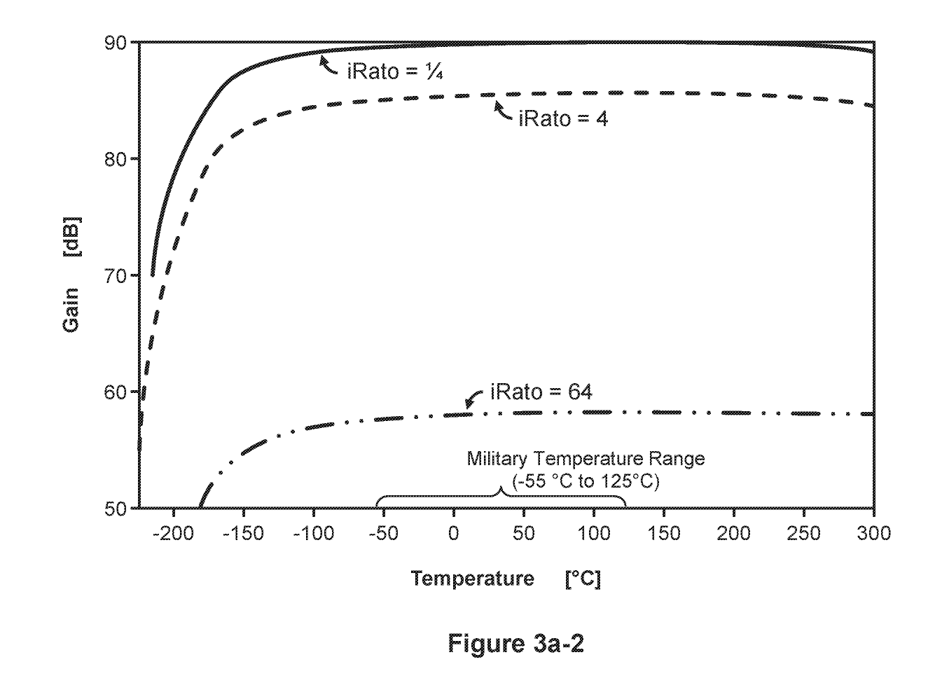

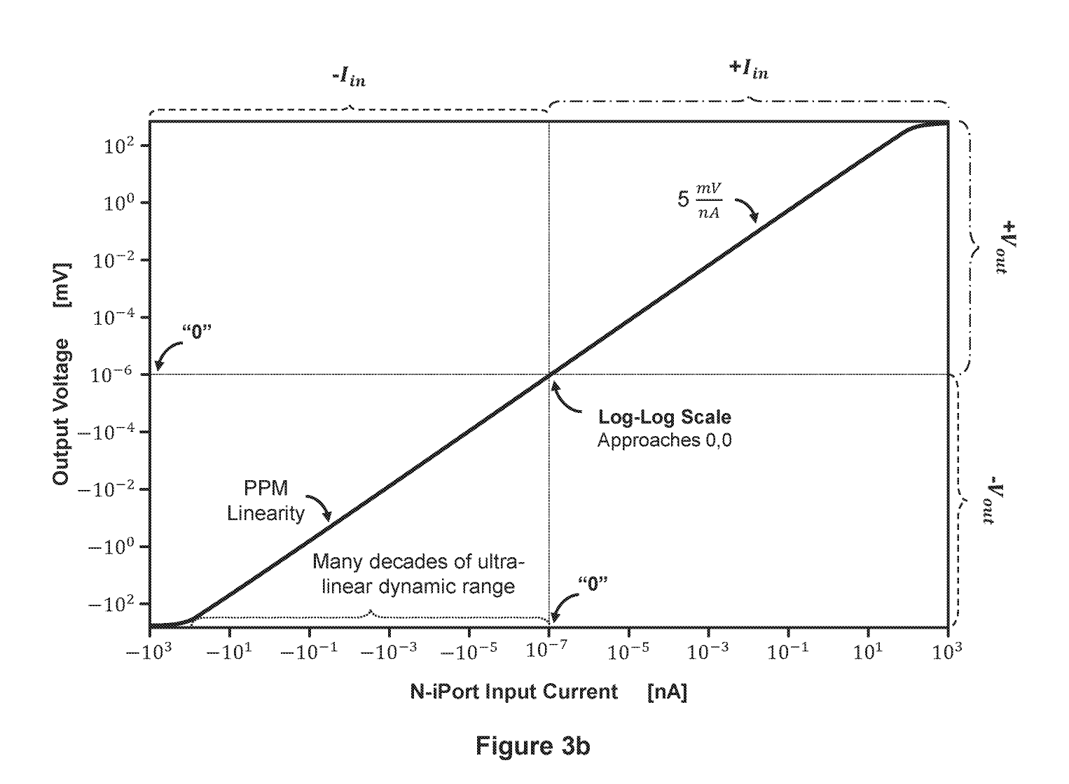

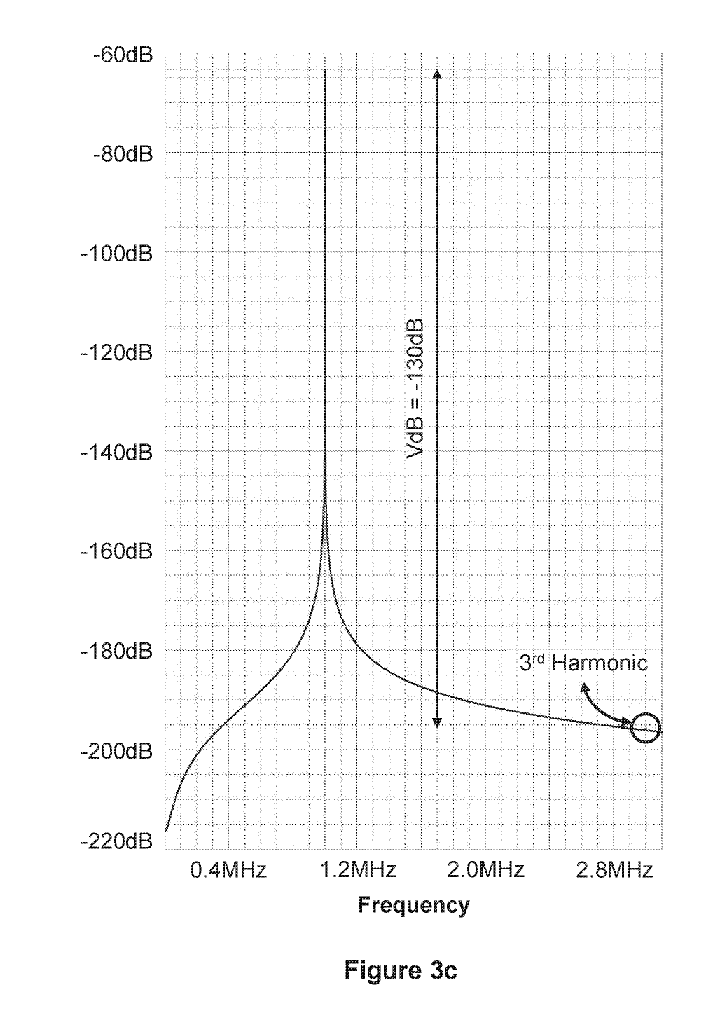

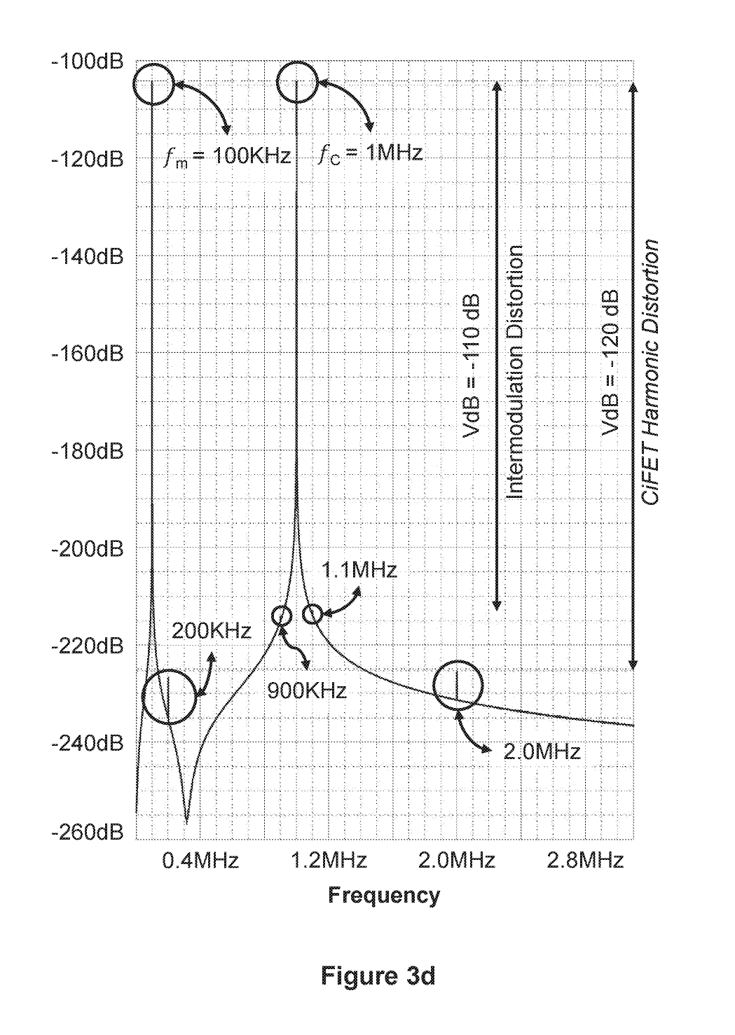

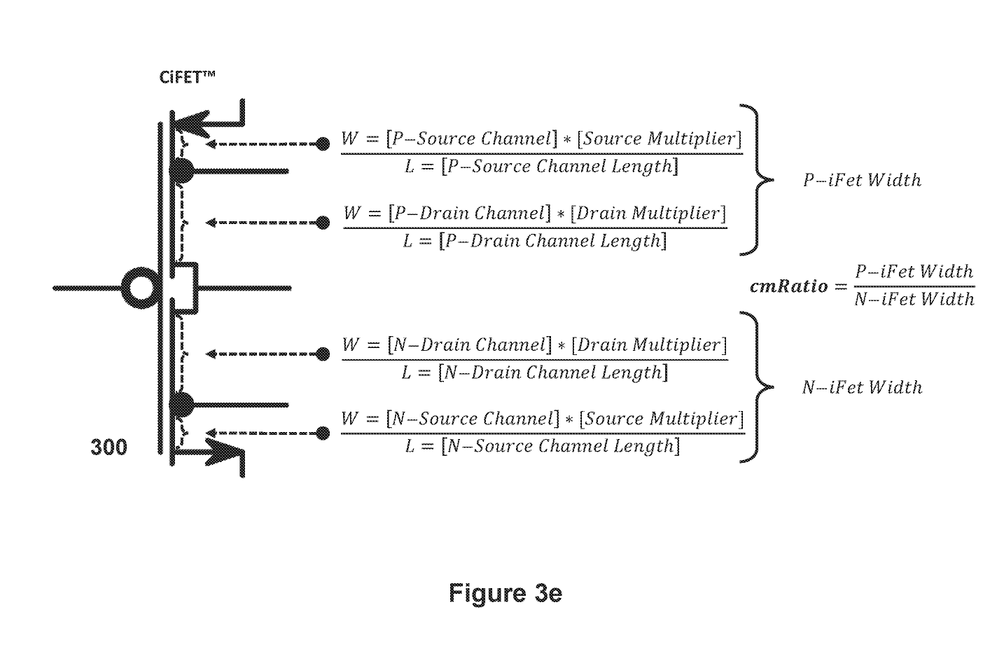

Referring to FIG. 1c, consider further the case that where in order to develop the highest signal to noise ratio signal from the signal source it is necessary to pass the most power from the signal sources projected power into the receiving circuits front end section. Circuit theory defines the process, load the signal source with a matched loading resistor. When the signal source is loaded in this fashion and when the loading resistor value R_{L} is equal to the internal Thevenin resistance R_{TH} of the Thevenin source, the product of the voltage across and the current through the load will be the highest (at β). If interfacing with a high impedance voltage source, the CiFET input impedance can be adjusted through its iFET Ratio, which is Width/Length of source channel over Width/Length of drain channel of iFET (see FIG. 3e), to provide within limits a high enough input impedance that it will not load the voltage source. In a similar fashion the CiFET input impedance may be adjusted to a very low value is needed to measure the short circuit current I_{SS}.

Referring to FIG. 3e, the iFET may be constructed with different length to width proportions for drain and source channels with very predictably differing results. As stated above, CiFET input impedance may be adjusted by ratio (iFET Ratio) of is Width/Length of source channel over Width/Length of drain channel. The iFET Ratio represents relative iFET channel strength ratio (Source Channel strength/Drain Channel strength). More specifically, it is charge density ratio between operating iFET channels.

The complementary pair of PiFET and NiFET is normally set to the same iFET Ratio, but both P-channels are wider by the common-mode Ratio (or cmRatio) which is used to approximately balance the P to N mobility differences. The cmRatio centers analog output voltage signal swing near half-way between the power rails and forms a common-mode voltage (Vcm) as analog ground. This enables maximum symmetrical dynamic range which tends to have complementary power supply noise cancellation while nullifying nonlinear harmonic terms in the output.

The cmRatio (the P-to-N ratio of a CiFET) is a self-generated common-mode analog ground voltage (Vcm) that is formed by connecting the drain-to-gate of a replica CiFET making the Vcm adapt to prevailing semiconductor parameters.

One other consideration in channel sizing is limiting worst-case pass-through (totem-pole) current in order to operate the CiFET within maximum allowed DC current pass-through inside the transistors and related contacts and consideration of local heating and power-speed trade-offs. The voltages, current and power transduced from such a Thevenin power source is shown in FIG. 1c, that, as previously stated, the peak power (at β) is transferred when the load resistance R_{L} matches the signal sources internal impedance R_{TH}. In addition to maximizing power transfer to the loading resistance one can use multiple measurements of the voltage across different loading resistances to look back into the driving signal source.

Consider FIG. 1a, further consider that the V_{OC} is set to 2 volts and the internal Thevenin resistance R_{TH} is set to 1000 ohms. Furthermore, consider the current that will flow in the circuit if the load resistance R_{LOAD} is set to a value of 200 ohms. In this case one will find the loop current that flows is 1.6667 milliamps, and the voltage across the 200 ohms will be (200)*(0.0016667)=0.3333 volts. Further consider that the R_{LOAD} resistor is set to a second value of 500 ohms, again the loop current is calculated as and found to be 1.3333 milliamps and the voltage across that 500 ohm resistor is now found to be 0.666667 volts.

One can use these two conditions set by the two values of load resistances to be sufficient to develop a set of simultaneous equations from which one can calculate the internal open circuit voltage V_{OC} and the Thevenin resistance R_{TH} of the internal black box. Calling the first value of resistance r2=200 ohms and the second value of resistance r3=500 ohms the following equations can be developed to solve for the open circuit voltage and the internal Thevenin resistance. The voltage across the r2 and r3 resistors is designated v2 and v3.

$$Voc = \frac{- ( r 2 * v 2 * v 3 - r 3 * v 2 * v 3 )}{( r 3 * v 2 - r 2 * v 3 )} ; Rth = \frac{- ( r 2 * r 3 * v 2 - r 2 * r 3 * v 3 )}{( r 3 * v 2 - r 2 * v 3 )}$$

When the measured values are inserted, (v2=0.33333 v, r2=200 ohms, v3=0.6667 v, r3=500 ohms) the calculation is performed the results produced are the estimates of V_{OC}=2.00058 and R_{TH}=1000.36 ohms. These internal black box values are deduced from measurements made on totally accessible external components. One has is a sense looked inside the power source and extracted its nature.

One needs the values drawn from two such measurements made on two different loading resistances to supply enough data for the two simultaneous equations. Clearly as noise and system variability effect raw data so will the quality of the estimates be affected. Additionally, these types of measurements can be made over and over again and thus one can track any changes that occur inside the driving power source.

For example, if one is taking measurements from implanted electrodes one can monitor the R_{TH} estimates as an indicator foretelling a change in the implanted electrode tissue connection. If the connection begins to fail the R_{TH} will change. One must also include in this deduction the other sources of impedance in the measurement loop in order for the measurement to be meaningful. For example, an electrode will present a resistance of where R_{electrode} is the electrodes inherent interfacing resistance,

$${R}_{electrode} = \frac{1}{4 πγ {r}_{electrode}}$$

where γ is the conductivity of the electrodes local tissue surrounds and r_{electrode} is the radius of the electrode in question. For normal 7 French implanted pacing electrodes the R_{electrode} presents a value of approximately 500 ohms.

One can process the readings taken at two different load resistance values and use those values to populate two simultaneous equations that will solve for the source's hidden open circuit voltage and its internal Thevenin resistance. One can then look back into the signal source and track its internal changes if that adds data to the desired measurement from a sensor. Of course, the real data will produce real results with uncertainty, multiple measurements and data averaging will smooth the estimated results.

The CiFET family is able to transduce from current sensors such as a photodiode, which produces a very low level current output signal. The photodiode process modulates the reverse leakage current when photons strike its surface to produce a delicate current source. This tiny modulation is the signal and to transduce it accurately the photodiode must deliver that current to a low impedance node that will accept that current, and produce an amplified signal that faithfully tracks the input current. The CiFET provides such a low input impedance iPort and turns that current input into an amplified voltage output while having a wide enough bandwidth, an ultra-low signal to noise ratio and an ultra linear transform so as to faithfully provide that photodiode signal transduction. In the opposite extreme a pH meter presents a high output impedance and needs to be transduced as an unloaded voltage source. Drawing current from a pH sensor, where will change its presented sensor voltage so that it no longer reflects the open circuit voltage. This reduces the pH meters accuracy and would make an unsuitable transducer. The CiFET family is able to provide the appropriate loading impedance across the broad spectrum of current and voltage source needs, which is to say it can provide, by design, both high and low input impedances as demanded by the specific sensors needs. The CiFET family does this while providing an extremely high bandwidth and ultra-low signal to noise ratios, it provides essentially transparent amplification.

The CiFET amplifiers also have another hidden characteristic(s). When the DC channel bias current flows through the CiFET structure, the complimentary iPort nodes are driven to a specific DC bias voltage. In the case of the n-channel iPort depending on the iFET Ratio, (the ratio of the width to length ratio of the source channel and the width to length ratio of drain channel of a iFET), this DC offset voltage can be made to range from the high millivolts to the hundreds of millivolts. If that DC voltage is monitored and calibrated, it provides a high-quality measurement of the CiFET's temperature. In essence the CiFET has its own built in temperature sensor. The story continues however, as even though this DC voltage will shift with temperature, the throughput gain and the frequency response of the CiFET amplifier does not appreciably change. One could put a CiFET family amplifier on the distal end of an oil drilling rig and have that amplifier transduce the desired sensed signal, with stable gain, and also transduce the temperature at that distal end. The operational temperature range of the CiFET family also far exceeds the current military specification temperature range as shown in FIGS. 3a-1 and 3a-2. The performance is predicted to remain constant across a wide range of iFET Ratios.

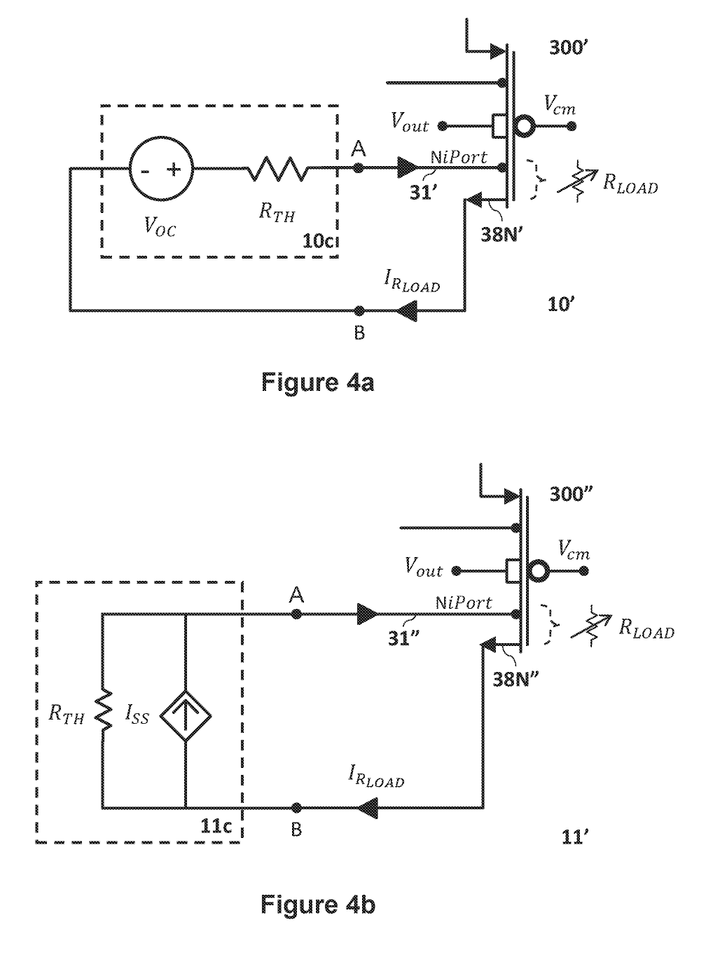

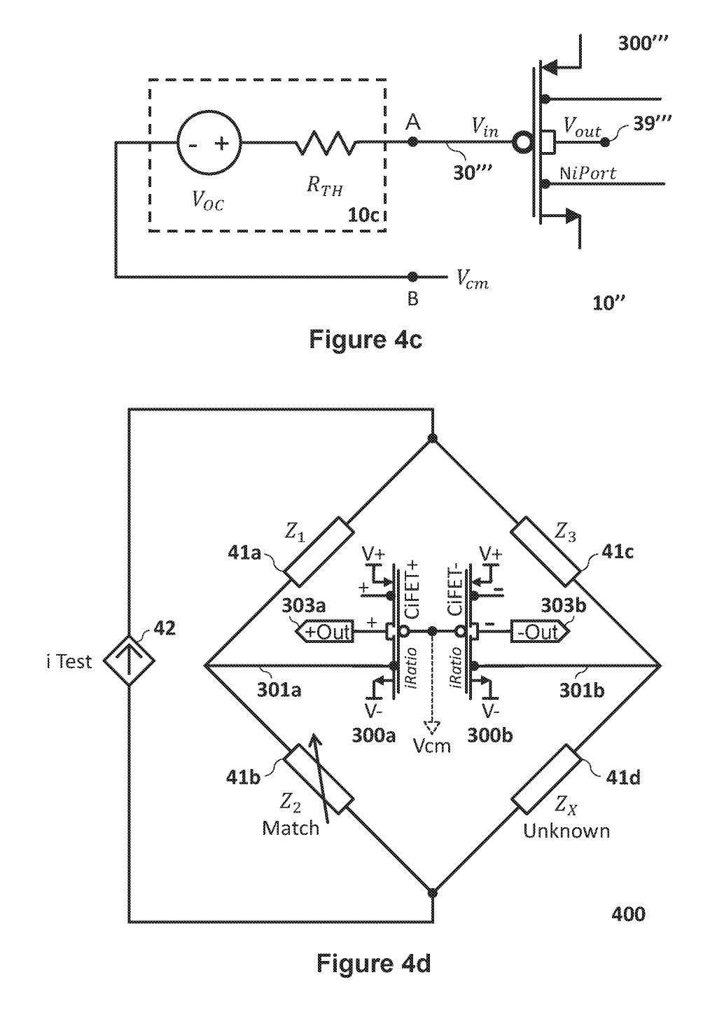

FIGS. 4a and 4b show exemplary drawings for CiFET applications and its adaptabilities as current sensor or voltage sensor amplifier. FIG. 4a illustrates a diagram 10′ of a voltage signal sensor model using a CiFET 300′, where the adjustable resistance R_{LOAD} is replaced with CiFET 300′, in which NiPort 31′ and source terminal 38N′ of the NiFET of CiFET 300′ is connected in series with Thevenin equivalent voltage source 10c (V_{OC} and R_{TH}). Terminal 30′ references to a common mode voltage V_{CM}. The output Vout of CiFET 300′ references to the common mode voltage V_{CM} such that it will avoid inclusion of power supply and ground noise(s) to its output.

FIG. 4b illustrates a diagram 11′ of a current signal sensor model using a CiFET 300″, where the adjustable resistance R_{LOAD} is replaced with CiFET 300″, in which NiPort 31″ and source terminal 38N″ of the NiFET of CiFET 300″ is connected in series with the current source 11c (I_{SS}/R_{TH}). Terminal 30″ references to a common mode voltage V_{CM}. The output Vout of CiFET 300″ references to the common mode voltage V_{CM} such that it will avoid inclusion of power supply and ground noise(s) to its output.

Coupling the virtually transparent amplification capabilities of the CiFET with the capabilities offered by inexpensive microprocessors, it is now possible to transduce and process this sensor data both in a point by specific point fashion or in a real time continuous fashion. The CiFET family addresses this need by much more than just providing unmatched analog performance. The CiFET family is compatible at the silicon level with any process node than can produce a CMOS logic inverter. The CiFET analog performance scales into the geometry of high single digit nanometer scale process nodes as judged by modelling on software such as Cadence or HSpice. The analog CiFET structures and CiFET based logic constructs can reside on the same silicone next to, and intermixed with optimized CMOS logic constructs. CiFET needs no extra add-ons to the standard process node considerations that are optimized for digital structures, save for the ability to adjust the width and length of the CiFET geometries and possibly the lower supply voltages where the CiFET can still operate. There are no extra process node add-ons, whether one uses planar, FETs, FinFETs or other type of FET structures and across the wide range of process node scales. Analog designs are portable, if the CiFET circuit works at 180 nm it will work at other smaller size(s) as well. This design compatibility extends to the circuit simulation programs used to model CiFET circuits; more will be said on this later in the document. The CiFET structure is an electric field driven device that uses the produced controlling transconductance. The CiFET structure is applicable to any process whether based in silicon, other materials (like germanium, nano-tube, etc.) or even designed into bio-protein structures that can produce and affect a transconductance type of control over another of the devices parameters. The use of the term transistor may include these new developing transconductance producing structures.

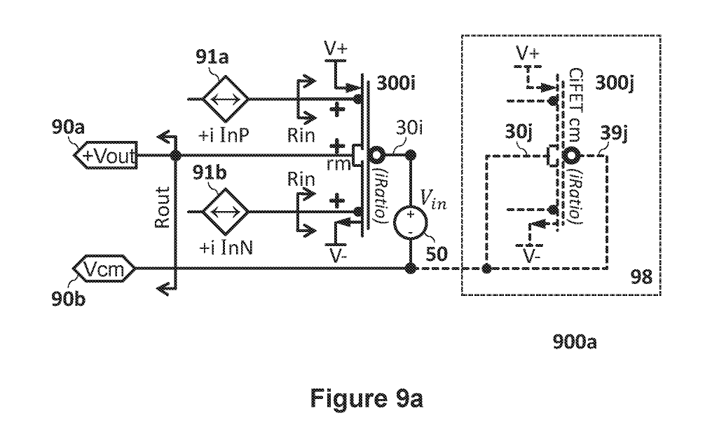

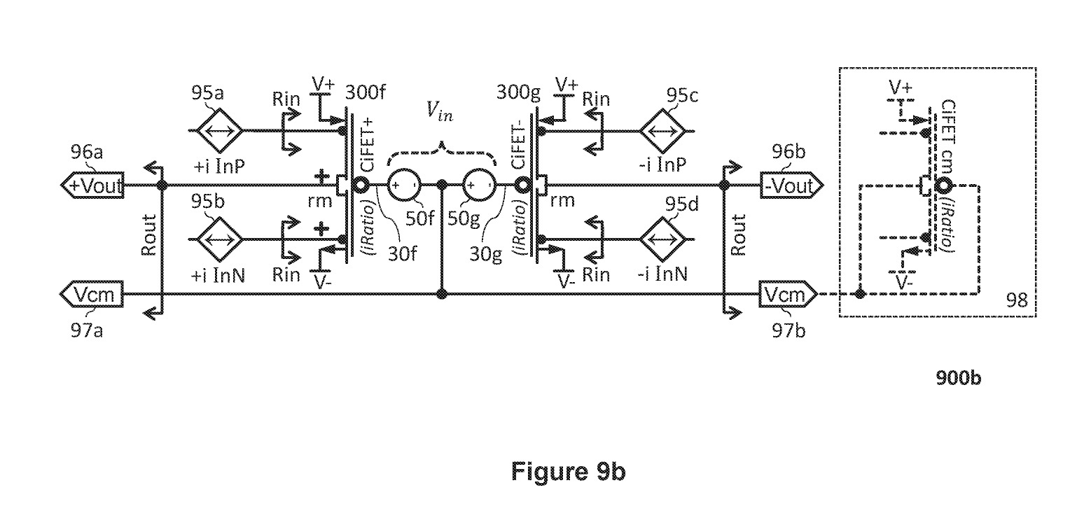

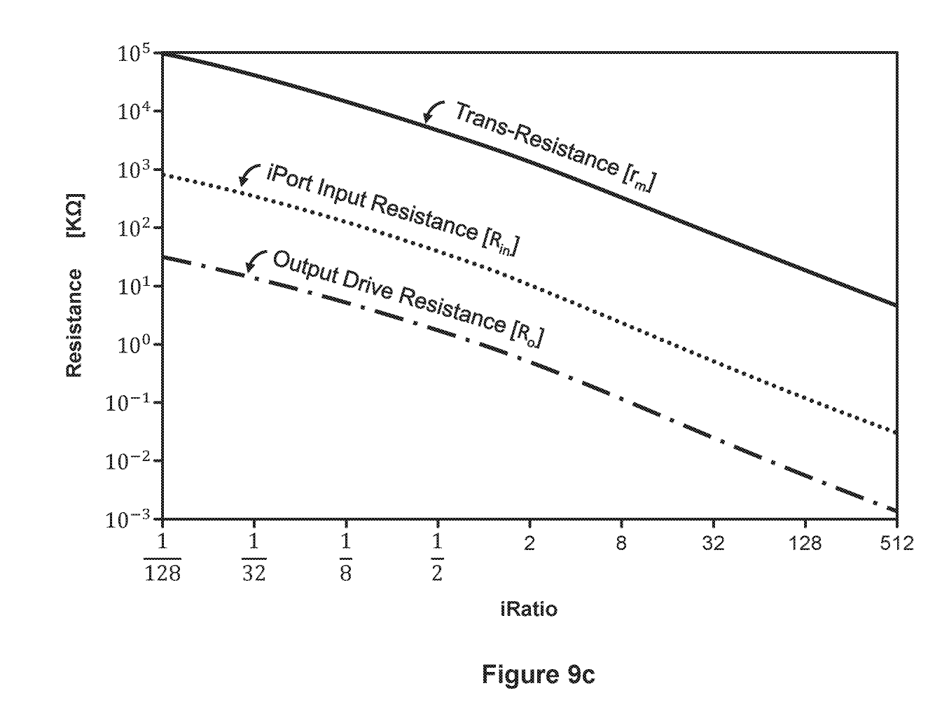

FIG. 4c shows a diagram of a high-input impedance signal sensor model 10″ using a CiFET 300′″, where CiFET 300′″ is connected to a voltage signal source 10c (V_{OC} and R_{TH}) through its Vᵢₙₚᵤₜ 30′″. CiFET 300′″ operates in a high-input impedance mode for monitoring/sensing the voltage signal source 10c. Notice by referencing signal swings to the common mode voltage bias generator V_{CM}, the signal path avoids supply and ground line noises. Additionally, as the common mode voltage, V_{CM}, is generated by a common mode voltage generator, an example of which may be a replica IC co-resident CiFET, such as reference numeral 98 shown in FIG. 9a. This common mode bias voltage generator output self-adjusts to the peak performance point of the CiFET structure. The produced biasing voltage incorporates the realized process and global parameters like ambient temperature to continually adjust to this optimal common mode bias voltage point.

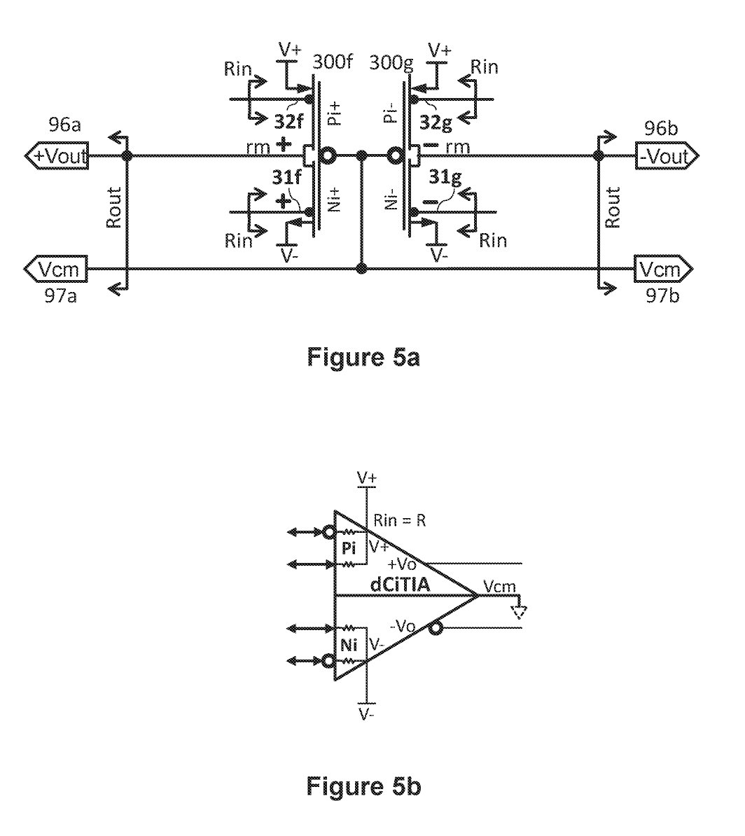

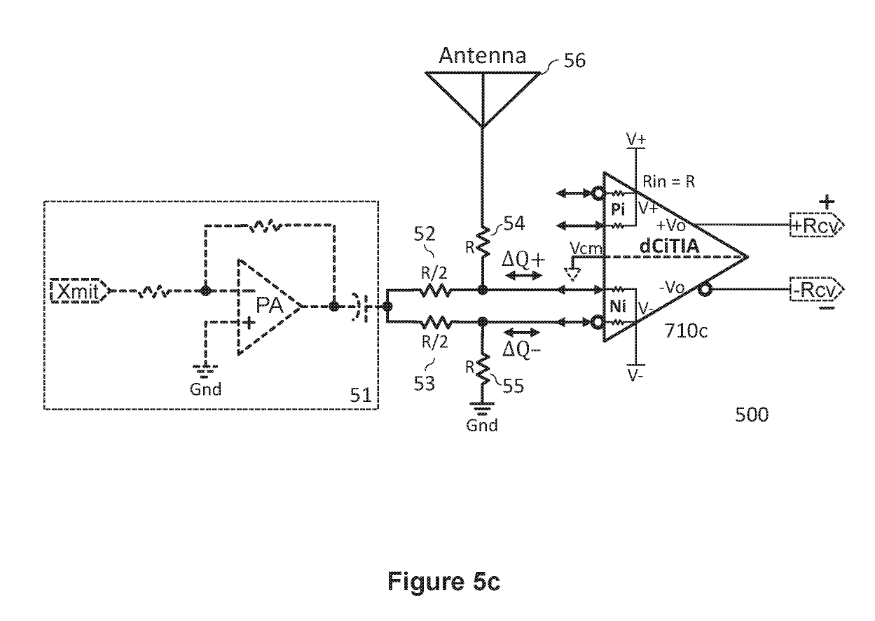

CiFET family analog circuits comfortably sit next to or comingled with the projects digital CMOS circuitry, and use the same design software as is used in the industry today. The improvements the CiFET design brings include compatibility with existent silicon process nodes, compatibility with current design and layout software and the CiFET analog structure brings new capability to analog designs that can dramatically reduce the silicone surface area needed for the same analog function, in some cases the surface area reduced is by a factor greater than 100:1 as in the case when the required silicone surface area of a folded cascade differential amplifier is compared with its CiFET TIA counterpart. In addition, the CiFET family brings forth new analog design functions such as a minimalist Wheatstone impedance bridge detector FIG. 4d to a circuit that can transmit and receive at the same time FIG. 5c. Details of this circuit are presented in the later application section. Often the CiFET produced design eliminates the high value resistors that are sometimes used in low photodetector current to voltage detectors and transducers. By eliminating or reducing the need for the high value resistance's the CiFET net circuit noise is reduced further because the Boltzmann resistor noise of the various circuit components are either reduced or simply eliminated.

The use of current sensing, while certainly familiar, it not the default approach taken with many signal transduction circuits. As an example of the benefits of this type of signal source interfacing consider one needs to transduce from a volume conductor that has many simultaneous signal sources all broadcasting at the same time as is the case when sensing depolarization from implanted electrodes. Then further complicate the measurement problem by having all these Thevenin sources have the same open circuit voltage. If one considers the signals that may be transduced from two electrodes in this volume that signal could be transduced using a voltage mode, a current mode, or a power mode type of measurement. The voltage mode would measure the open circuit unloaded voltage from the chorus of simultaneous signal sources. It would be hard to say this voltage is from that specific source or region. If one alternatively shorts the two electrodes together and one measures the short circuit current that flows several new physical realities following Maxwell's electromagnetic field rules come into play. This technique inherently increases the signal to noise ratio from distant signal sources compared to nearby sources.

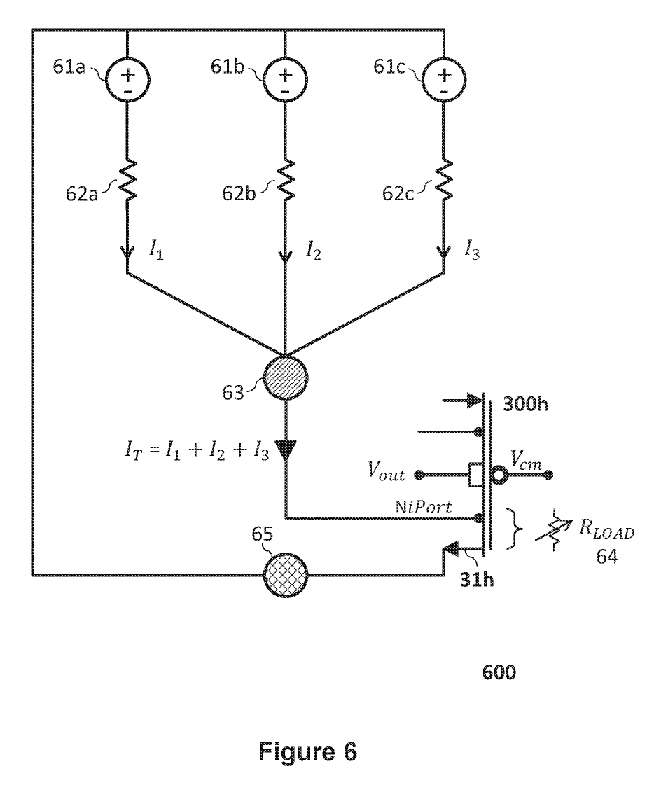

An example of this process is shown as a model 600 in FIG. 6. Three signal sources 61a, 61b and 61c have been represented, all with the same open circuit voltage V and each with a different source resistance 62a, 62b and 62c, respectively. Access resistance to the close source is R₁ 62a: 100 ohms, R₂ 62b: 1000 ohms to a near source and R₃ 62c: 10,000 ohms to a distant source. The load resistance R_{LOAD} 64 is placed between the two sensing electrodes, probe electrode 63 and reference electrode 65, one in the midst of the driven action and one remote from that action for simplicity. If resistive value of R_{LOAD} 64 is high, the probe electrode 63 will float to the voltage open source voltage potential. The signal from the distant source may contain more noise, but its open circuit voltage V will register at the probe electrode 63 the same as the voltage open circuit potential of the close source. Now consider the case where the value of the load resistor R_{LOAD} 64 is very low in the tens of ohms region. In this case each signal source now supplies its short circuit current to the summing point at the probe electrode 63. The close source supplies a V/100 (or V/R₁) amount of current (I₁), the near is V/1000 (or V/R₂) amount of current (I₂), and the far supplies a V/10,000 (or V/R₃) current (I₃). The measurement technique improves the signal to noise ratio of the close sources without any addition signal processing or noise inducing steps. In FIG. 6, the term I_{T} represents the sum of the currents I₁, I₂ and I₃ that represent the input current to NiPort 31h of the CiFET 300h. In the figure three such signal sources are presented, in an in-vivo situation there are hundreds of simultaneous depolarization sources that are all producing driving signals at the same time, each with their own Thevenin source impedance. Most in-vivo depolarizations produce roughly a 20 mv peak driving open circuit voltage which is the peak of the cellular transmembrane potential that is produced as the inside and outside of the active depolarizing cell swap ions. The V_{Rload} refers to the voltage that is produced across the external loading resistance connected to the signal source in question. The concept of V_{Rload} is further developed in this section. Earlier disclosures of this technique, U.S. Pat. No. 5,156,149, used conventional operational amplifiers and several external components to achieve this measurement technique. Noise inducing feedback techniques where employed to produce a virtual node on the probe electrode where the summed currents could be tallied. That same measurement may be performed by one biased CiFET TIA amplifier with the implanted electrodes connected to the respective differential iPort inputs. The CiFET's iPort inputs will provide the R_{LOAD} 64 to the probe 63 and reference 65 electrodes, and transduce the current signal directly to a produced differential output voltage. Current measurements in a volume conductor offer another benefit inherent and thus noiseless to the technique. When measuring the potential as one moves away from a sphere of charge, the signal, the voltage drops inversely with distance from the charge source. The larger the region from which signals are included, the more noise is swept by the electrodes. When measuring a scalar current derived from the surface integration of the normal current flux in the volume, the measurement in effect is measuring the electrode local electric field from the dynamically changing sphere of charge. The electric field drops off with an inverse square relationship with distance from that sphere of charge. The volume from which the electric field measurement is drawn is smaller and therefore the region from which the noise sources can intrude is reduced. The signal to noise ratio of the current inherently has a chance to be larger than a voltage measurement made from that same electrode. This ability is very important when using in-vivo electrodes to sense body depolarizations from cardiac or neural events.

Improvements in usable bandwidth, lower supply voltages, input drive flexibility, signal to noise performance improvements, ultra-low intermodulation fidelity, ability to be integrated with digital CMOS process nodes, tolerant of process variability, design transportability with process node scaling, compatibility with existent software design and layout tools, ability to produce standard analog circuit functions and the expansion of the building blocks available to analog designs are all components of improving the art of sensing from signal sources.

The CiFET extends or brings forth new capabilities in all these areas. Several circuit applications will be detailed later to show a traditional Wheatstone bridge application and a new circuit configuration that can be used to sense from an implanted electrode or sense from an RF antenna. The linearity of the CiFET shown in FIG. 3b also extends over many decades of current signal input. This linearity and decades of dynamic range contributes to the lack of harmonic distortion seen in the Fourier transform harmonic analysis seen in FIGS. 3c and 3d.

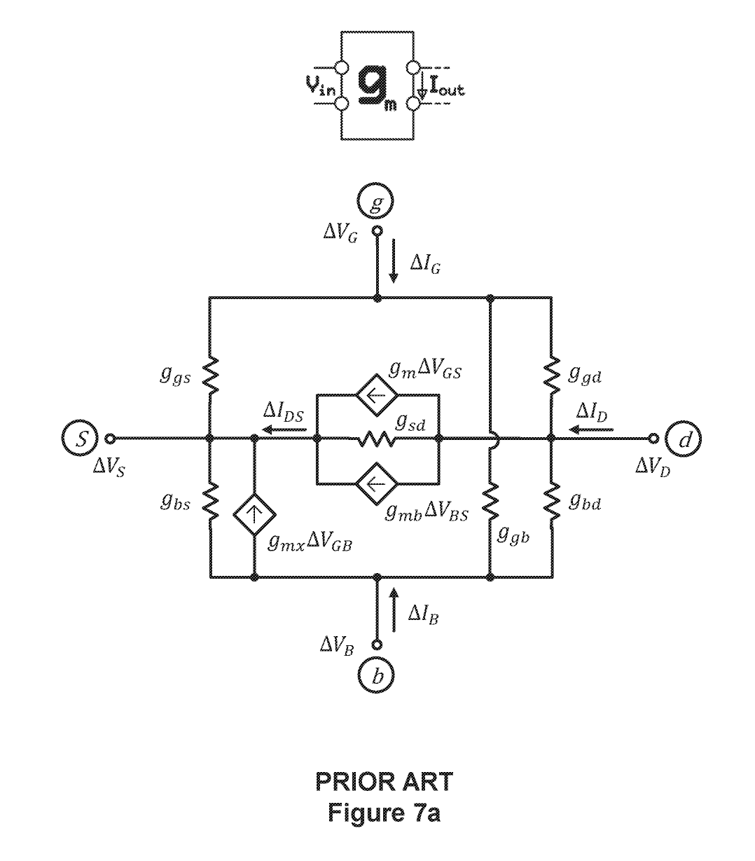

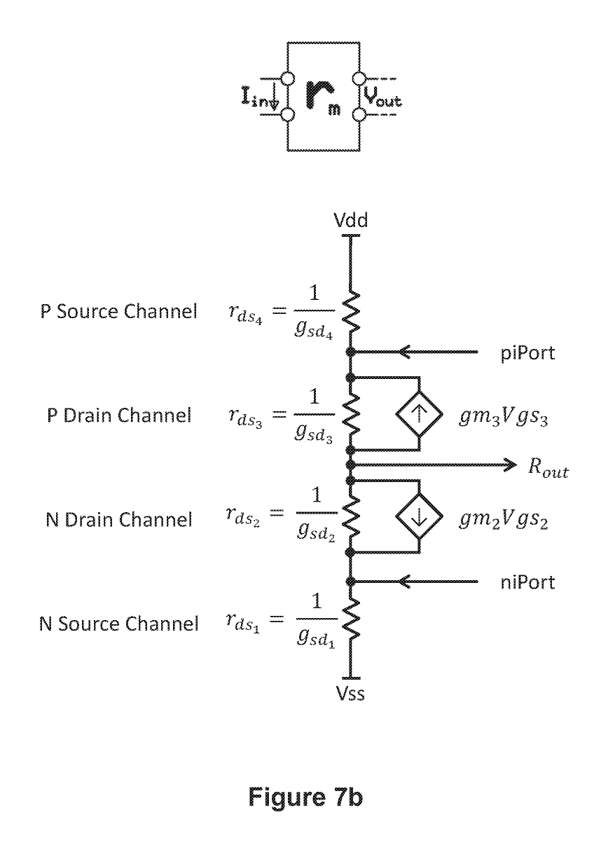

The CiFET structure produces a fusion electronic device, its layout appears as two conjoined enhanced MOSFETs coupled with its complimentary conjoined MOSFET pair (or complementary pair of iFETs) to produce a CiFET structure. This simple structure belies what is going on under its hood. To address the functional parts of the CiFET a good place to start is to examine the nature of the p and n source channel. In FIG. 7b, a small signal model of the CiFET is presented, which is based on the teachings of the book by Y. Tsividis, entitled “The MOS Transistor 3rd edition” (“Y. Tsividis”) at pages 394-395. Note that no small signal current flows in the n and p source channel. The MOS drain to source transconductance current source is not present. The p and n drain channel small signal current dependent current source is included. CiFET would not have its ultra-wide bandwidth and it ultra-low noise performance comes into existence because of the intimate connection between the elements that connect to the common path through the CiFET structure.

FIG. 7b illustrates the various small signal elements of CiFET, the current input p and n iPorts, and the output voltage port. The gates are all connected to the biasing common mode voltage V_{cm}. This common mode voltage V_{cm} is developed in a dedicated CiFET.

In practice, there may be design advantages to connecting different V_{cm}'s to the various gates. By using this approach, the various transconductance relationships may be further adjusted to the benefit of the final circuit design. Indeed, while the common gate connections may satisfy many circuit needs by adjusting the specific gate voltages, one may deliberately shift any of the complementary channel gate V_{cm} to produce a different operating point either deeper or further out of the that common gate voltage inversion region.

There are many transconductance ratios that are defined to model the small signal operation of an iFET they are adequately detailed in many books. It is widely accepted that the MOS Operation book by Y. Tsividis does a particularly good job in their descriptions. Two of those descriptions will be brought forth. The first is the transconductance of the MOS device which relates how the drain current will react to a change in the gate to source voltage of the device in question while many other parameters around the device are held constant. This transconductance partial differential equation is presented below and the term is used in many of the descriptions.

$${g}_{m =} \frac{\partial {I}_{DS}}{\partial {V}_{G}} {\vert}_{{V}_{S} , {V}_{D} , {V}_{B}} \qquad ( 3 a )$$

The other transconductance term that is used is the change in the drain current with respect to a change in the drain to source voltage of the device in question. This equation is presented below and is used in some of the presented figures.

$${g}_{sd =} \frac{\partial {I}_{DS}}{\partial {V}_{D}} {\vert}_{{V}_{S} , {V}_{G} , {V}_{B}} \qquad ( 3 b )$$

In FIG. 7a which was taken from the Y. Tsividis book the common transconductances around a simple MOSFET structure is shown. All have similar descriptions a change of a selected current to a change in a selected voltage. For more detail on these transconductances the reader is referred to Y. Tsividis's book 3^{rd} edition, page 395, where the balance of these terms are detailed and in a form that is commonly used in the electrical engineering surrounding MOSFET use.

One term is newly defined for the CiFET, the change in drain current when the source voltage is varied while holding the gate voltage, the substrate voltage and drain voltage constant. It will be assumed to be nearly identical to the gₘ term in MOSFET models which refers to the change in drain current with respect to a change in the gate to source voltage. Referring to FIG. 2c, the difference here lies in the fact that normally the gate is signal driven here the gate is held at a constant voltage and the drain channel 35e or 36e is driven by the small signal produced by the iPort current injection at NiPort 31e/PiPort 32e.

Starting from both the NiFET and PiFET source channels, 33e and 34e, it is noted that with the constant V_{cm} voltage to output 39e and biased to input Vin− 30e, for example, roughly at a value of V_{dd}/2 that source channels 33e and 34e will be in the super inverted channel mode, that is the gate voltage is so high that extra electrons are attracted from nearby areas to excessively populate the channel under these sources gates 38Ne and 38Pe. It is from this large excess of channel electrons that the DC CiFET channel biasing current is drawn. A typical value for this DC current with a one (1) volt supply voltage would be about one (1) microamp. The specific operating point of the source channel depends on the CiFETs iFET Ratio and the supply voltage. The iFET Ratio refers to specific channel W/L ratios found in the sources and drain channel of the same substrate type. Often the iFET Ratios of the complimentary pairs that make up the CiFET structure are set the same to ensure mirror like operation in the device, this, however, is not an absolute requirement of the CiFET design. The iFET Ratio along with the V_{dd} supply voltage determines both the p and n iPort small signal input impedances and the Vₒᵤₜ output voltage driving source impedance. The operation of the excess source channel electrons follows the rules of diffusion and migration flow as determined by the drain to source DC voltage of the source channel iFETs. The source channel of the NiFET and PiFET 33e and 34e, are configured as constant current sources as they are driven by the constant common mode voltage drive V_{cm}. This channel's drain to source voltage may vary from millivolts to hundreds of millivolts. The source channel 33e and 34e iFET current source action will be compromised as the drain to source voltage falls. However, with its excess electrons, even if they are not driven by migration still provide an iPort low impedance source impedance to analog ground and supports the use of the CiFET as a current signal source sink. These current sources perform better as their source degeneration begins to function. Note that in operation no small signal current flows in either the NiFET source channel 33e or PiFET source channel 34e. The small currents are limited to the n and p drain channels, 35e and 36e, as will be discussed.

Current injected into the NiPort node quickly merges with the background DC channel current. This injected current interacts with the small signal input impedance presented to the signals current drive at the iPort. This current produces a small voltage signal on the NiPort 31e. Note that the NiPort 31e is both the drain of the source channel 33e and the source of the drain channel 35e.

Consider the case where the DC channel current Id has been established, this implies that all the silicon material and internal structure has had its bio-domain capacitive components fully charged to that bias point, so the shift from these existent bias points due to the injection of the signal current is minor. If the channel current is set to the 1 microamp levels the injected signal currents lie in the 10 to 100 picoamp range. As the parasitic distributed capacitance is fully charged and the small signal information is carried in the current modulation of the DC bias channel current and parasitic charging time is minimized. Changing channel current shifts the channels distributed voltages just slightly so that the current flow required by a displacement current equal to C dVc/dT is less than would be excepted if voltage level modulation would carry signal information. Less displacement charging current produces a wider device frequency operating range. This is in addition to the cascade Miller capacitance cancelling circuit structure increases the high frequency response.

Once the DC operating point of the CiFET has been established by the iFET Ratio in silicon it needs the specific value of the supply voltage to fix the final input impedance of the NiPort and operating point. The power supply voltage may be used to modify the CiFETs behavior and operating point in a dynamic manner. A CiFET can control another CiFETs supply voltage V_{dd} which would make all the properties of the CiFET dynamically adjustable, sort of like software rewriting itself to suit the immediate needs. Dynamic parametric control of the CiFET's properties can be implemented.

Referring again to the low frequency small signal model for an MOS transistor is given in FIG. 7a or in Y. Tsividis at pp 394. Many additional transconductance parameters are shown and ultimately needed to understand the flexible operation of the CiFET structure can provide. A familiar conductance in MOS analog circuit design is the basic transconductance of the MOS structure which relates the ability of a change in gate to source voltage to change the devices drain current. Equational it represents as gm=d(ids)/d(vgs). As the process node shrinks, the dimensions of the device get smaller and the transconductance increases and is partially responsible for the fact that CiFET designs scale to smaller geometries. The MOS action in turning a gate to source voltage variation into a drain current modulation is modelled as a current source in parallel with the source channel resistance as shown in FIG. 7b. The gm*vgs drain current source term interacts with its parallel loading resistances to produce a voltage. This voltage is the output voltage of the CiFET. The CiFET amplification factor comes from the small iPort voltage that is produced when it accepts an injected current. The source channel MOS transistor sits astride or on top of the source channel in intimate contact. When the source channel MOS is forcefully biased or clamped into exponential diffusion channel current mode bias point wherein small change in the gate to source voltage has an exponential control of the modulation of a fraction of the channel current. To this small V_{gs} signal the source MOS channel operates in a common source MOS amplifier configuration. One must remember however, that it is the source terminal of this transistor structure that is being driven rather than the gate. Therefore, this drives the current into the NiPort and causes the CiFETs output voltage to go up in a non-inverting direction as does an injecting current into the PiPort does. Current into either the p or n iPort causes the output voltage to move toward V_{dd}. Both iPort current injections produce a non-inverting output voltage swing.

The source channel operates in a superposition mode; it has the DC bias current flowing through it as it would through a substrate resistor. It also operates as a common source amplifier to the small signal drive. This modulated channel current is superimposed on the DC drain current. The source channel of iFET has a V_{gs} DC bias and its DC Vas imposed by the iFET Ratio of the devices and the V_{dd} powering the CiFET device. The DC Vgs of the source channel sets its operating point and sets it its position in the range of exponential operation as opposed to weak inversion operation which is normally associated with limited bandwidth. To an extent, the slow weak inversion performance is related to the sparsity of free electrons that are immediately available to respond to the fields imposed by the gate to source voltage. When the gate to source voltage produced transconductance is called upon to cause a fog like cloud of weak inversion produced channel free electrons that may not be in the right place, they must first migrate to the region of transconductance demanded action and then participate in the electron migration that the imposed condition demands. In the CiFET, the sparsity of weak inversion electrons is eliminated by higher than the threshold gate voltage which provides a background DC channel current source. There is an abundance of free electrons readily available, and the slow response speed normally associated with this two-step process is minimized because the background DC bias current makes free electrons readily and immediately available and able to participate in the migration demands of the exponential gate source voltage control. These free-flowing electrons are essentially on standby to turn the normally limited bandwidth of the exponential mode into a high frequency powerhouse.

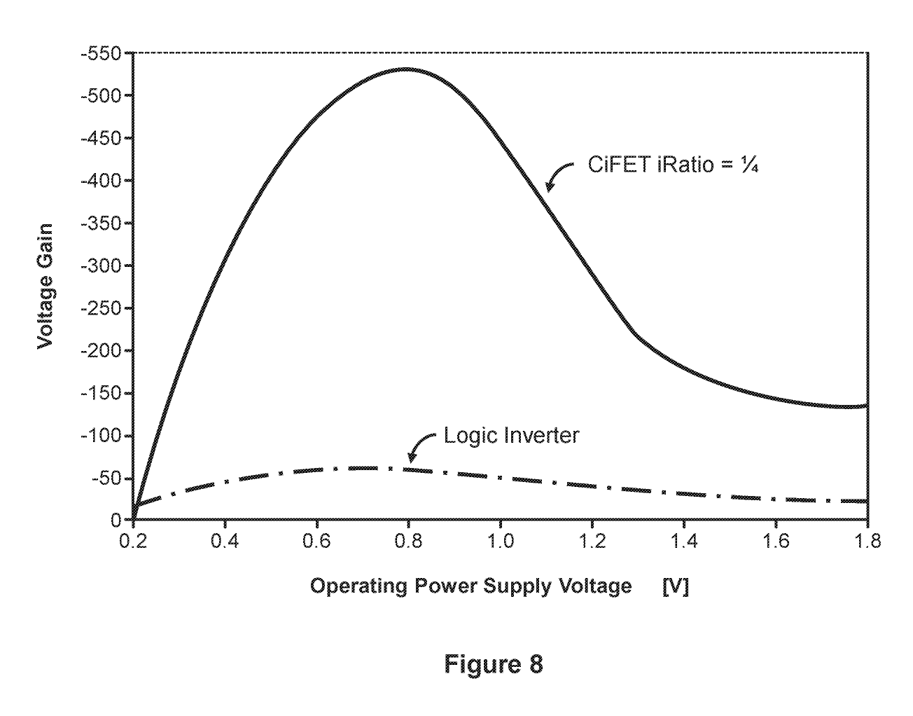

The flexibility of the CiFET structure is based in part on the user's ability to place the source and drain channel in a forced or clamped DC bias situation. For example, consider the case where the V_{dd} supply voltage is 0.8V_{dc}, this is the supply voltage where the CiFET yields its highest gain as shown in the FIG. 8. To generate this gain plot, the iFET Ratio is set to 1:4, the common mode voltage is driven to V_{dd}/2 or about 0.4 vdc. The NiPort DC voltage will be around 20 millivolts so the n channel source transistor is biased to about 0.4V-0.020V=0.380 Volts. Clearly the source transistor is biased into the strong deep or super-saturated inversion mode. The input small signal impedance the iPort presents will be low as the drain channel transistor will only have a few tens of millivolts across it and will be a very poor current source and will appear mostly as a resistor. If alternatively, the iFET Ratio is 4:1 the NiPort DC bias voltage will rise to a couple hundred millivolts, the common mode bias voltage will remain at 0.4 volts and the DC source V_{g}, bias voltage will change to about 200 millivolts. Now the N-channel source transistor has about 200 millivolts across is drain to source, so it will begin to behave like a real current source and not the passive channel resistor it was when that voltage was only 20 millivolts. The n-channel drain MOS transistor will now be DC biased to about 200 millivolts DC, that n-channel source transistor is still biased in the strong inversion mode but at a different operating point with different characteristics. In addition, one must consider the change in the various modelled conductance's around the standard MOS models as found in Y. Tsividis on the subject as mentioned earlier. The threshold voltage is about 350 to 400 millivolts in these source and drain channels of the CiFET. Threshold voltage has many definitions the growing use of C. Enz's definition of the gate to source voltage where the MOS channel current is due to ½ migration and ½ to diffusion is growing in use and acceptance.

The input impedance seen at the NiPort or PiPort is the parallel combination of looking into the drain of the source iFET. It is changed by the DC voltage across its source to drain connections and looking into the source terminal of the NiFET. Looking into this source, the small signal encounters a common gate source driven MOS amplifier configuration which presents low source impedance to the driving small signal. The specific iFET Ratio adjusts the input and output impedance as seen in FIGS. 9a, 9b and 9c. Adding to the output impedance of the source channel current source as that iFET's transconductance grows is the property of source degeneration which effectively increases the output impedance of that transistor. As the DC source to drain voltage drops on this n-channel source iFET, its ability to amplify and behave like an active device begins to degrade. This is seen as the gain of the CiFET structure drops when the supply voltage drops below 0.8 volts DC as seen in FIG. 8 for a CiFET iFET Ratio of 1:4. The maximum gain obtained for different CiFET iFET Ratios will occur at different DC supply voltages. While the CiFET still produces gain below this supply voltage the DC drain to source voltage of the source and drain MOSFETs begin to collapse as the transconductance of the CiFET elements begins to collapse. However, even when the DC supply voltage drops into the tens of millivolts the CiFET if connected to a capable driving signal source will draw current from that signal source and continue to offer usable gain even at these ultra-low supply voltages.

FIG. 9a illustrates a block diagram of an exemplary trans-impedance amplifier 900a using a single biased CiFET 300i. The separate iPort inputs, PiPort 91a and NiPort 91b, to both of the complementary inputs are detailed. PiPort 91a and NiPort 91b may receive input simultaneously with or separately, with different input impedances at PiPort 91a and NiPort 91b. The output voltage is delivered through the common drain connection of the complementary pairs node 90a. CiFET 300i may, simultaneously with or separately from PiPort 91a and/or NiPort 91b, receives input at Vin 30i for receiving a voltage signal 50 in a high-impedance mode. Note that all the gates of the CIFET 300i are commonly driven by the common mode voltage V_{cm}, 90b. The common mode voltage V_{cm} is generated by another separate CiFET 300j where the output 39j is connected to its common gates 30j; the common mode voltage generator 98 produces a bias voltage normally centered at around one half the value of the power supply voltage. This common mode voltage 90b sets the driven CiFETs biasing point to which its output signal voltage 90a swing is referenced. Being referenced to a derived midpoint bias voltage the CiFET sidesteps using either the ground or power supply as its reference voltage and thereby also bypasses to a great extent the noise that is carried on the lines. This is an important point when the CiFET is adjacent to on chip digital logic. The output of this single driven CiFET is single ended.

FIG. 9b illustrates another exemplary diagram of a transimpedance amplifier (or TIA) using two CiFETs 300f and 300g, biased by the common mode voltage 97a/97b. These pair of CiFETs 300f and 300g accept the driving inputs from one or any combination of one or more of PiPort 95a, NiPort 95b, PiPort 95c and NiPort 95d. When this pair is driven by a differential signal source through, for example NiPort 95b and NiPort 95d, it produces a differential output as shown in the figure between points 96a and 96b. Optionally, a common mode voltage (V_{cm}) may be provided by an external circuit 98, in the example, including a single CiFET, the configuration of which is the same as one shown in the circuit 98 in FIG. 9a. Similar to FIG. 9a, CiFETs 300f and 300g may, simultaneously with or separately from PiPort 95a, NiPort 95b, PiPort 95c and/or NiPort 95d, voltage signal(s) 50f/50g in high impedance mode at Vin 30f/30g.

As the iFET Ratio between the respective source and drain channels constructs change, the basic inherent properties of these circuits shift and adjust as well. Remember that these DC voltages may be adjusted at the circuit level by changing the power supply voltage of V_{dd} or by using several different DC gate voltages.

In summary, the source channels of NiFET and PiFET of the CiFET, operates as a super inverted device that provides a current source like operation or it supplies a low impedance electron rich conduction channel depending on the iFET Ratio. The drain channels of NiFET and PiFET of the CiFET, provides three functions simultaneously, 1) it passes the DC channel bias current like a resistor while 2) acting as a common source weak inversion, exponential gain amplifier to the small signal voltages produced by the injection of the NiPort current signal and this same transistor also 3) looks like a common gate source driven low input impedance CiFET amplifier to the iPort injected small signal current. The common source weak inversion amplifier provides the current gain of gmVgs to the drain circuit, where this current produces the CiFET output voltage signal as it interacts with the n-channel source to drain transconductance. The output impedance of the output voltage is also affected by the iFET Ratio. With adjustment the CiFET structure is able to produce a current input sensor with a 50-ohm input impedance while providing amplification to that signal and producing a transimpedance conversion to an output voltage with an output impedance of 50 ohms as well to drive downstream circuits. All of this occurs inside the CiFET structure with no external components.

Referring to FIG. 2c, the developed small signal currents only flow in the n and p drain channels 35e and 36e, they do not flow in the n and p source channels 33e and 34e. The driven iPort of the CiFETs determines the output voltage through its common source weak inversion operation. This developed small signal current is either supplied or absorbed by the driven iPorts complimentary partner. When the NiPort 31e is driven the drain to source voltage of the PiFET's source channel 34e and drain channel 36e varies dynamically to satisfy the concurrent simultaneous equations. By changing the drain to source voltage on the PiFET channel, in this example, the surrounding conductance's of those devices shift in such a way as to dynamically produce a real-time solution to these simultaneous equations. Indeed, the whole of the CiFET structure including the drain to source voltages, the iPort DC bias points, the device conductance's and the devices gm all shift to achieve this real-time solution. By changing a large number of parameters, the CiFET is able to meet the simultaneous demands and minimize the voltage changes seen anywhere in the CiFET structure. Since parasitic currents are directly proportional to voltage changes and the current that flows to charge these devices, the entire CiFET structure works to improve its frequency response through this disturbance distribution process. These adjustments are inherent in the designed structure of the CiFET, and the CiFETs net operation depends on the close intimate connections achieved as the complimentary sides of the CiFET are produced in close juxtaposition. One would see aspects of CiFET operation if the CiFET was constructed using discrete MOS transistors, but that configuration would not, could not produce the net wide bandwidth and the low noise performance seen in the actual IC level CiFET structure as the adjacency is part of the CiFET recipe.

It is important to realize that the CiFET operation depends on its complimentary pair which in a sense forms a perfect tracking load to the driving N-channel signal. The P channel complementary loads continuously change to perfectly absorb or supply the small signal current that flows in and between the N and P drain channels 35e and 36e. As the Vds changes across the loading CiFET, it changes its conductivities and its transconductance. The driven iPort, the iFET Ratio and the CiFETs V_{dd} set the stage and the response to the changes in the injected iPort current signal input. In response the entire CiFET structure changes its dynamic bias points in many places to provide the solution to the imposed parametric equations that define the CiFETs specific state.

The high frequency performance can be traced partially to the pre-charging of the distributed internal capacitances and the short space constants for the free electron transits that is commanded by the weak inversion mode and the ready availability of free electrons from the driven DC channel bias current.

The case of a single iPort driven by a small signal current has been discussed as well as how the CiFET output voltage comes to be. Now the definition of the signal input needs to be expanded. Just as the NiPort exists in the CiFET structure so does a PiPort node. These two nodes can be simultaneously driven. Each will have a different DC bias voltage, but both iPorts operate essentially the same. A small signal current injected into either iPort will cause the CiFET output voltage to go up, and conversely if you pull current from the node the output voltage will drop. When both iPorts are being simultaneously driven each uses the other of the complimentary pair for its active tracking load as was discussed for the single input to the NiPort. In the double iPort driven case another set of simultaneous equations are being dynamically satisfied, solved and their results are combined and joined by superposition.

The specific input and output impedances are determined by the process set iFET Ratios and the V_{dd} power supply. The resulting CiFET operating point along with its operating properties are also determined by these settings. These settings may be changed at manufacturing time or by modulating the power supply in the final circuit. The flexibility the CiFET brings to any sensor interface problem expands the breadth of solutions approaches that may be brought to bear on the specific measurement and signal transduction needs.

CiFET designs use the same MOS design rules that are taught and discussed in many books on MOS device operation and analog MOS designs. The transition from a MOS analog current mirror based design to a CiFET analog design is a process of extending one's design portable intellectual design portfolio. The repurposing of the analog MOS current mirror in the CiFET design along with the entire complimentary CiFET structure reduces analog function power, and lowers the possible V_{dd} power supply voltage, which must occur for CiFET designs to scale to smaller process nodes. In addition, the silicon chip surface area required for a folded cascade differential amplifier is reduced by a factor of more than 100 with a CiFET design. Only differential pair of CiFETs are needed for the signal amplification pathway and another to generate the common mode bias voltage. By using the common mode voltage that is roughly V_{dd}/2 much of the noise carried in from the ground rail and the power supply rail is avoided, this fact adds to the remarkable signal to noise figures produced by CiFET amplifiers. The V_{cm} bias path 98 is shown in FIGS. 9a and 9b. Cadence predicts the signal to noise ratio of a signal CiFET amplifier to be in excess of 180 dB, with bandwidths extending into the high hundreds of gigahertz. The CiFET structure can be produced by any process node (planer MOS or FinFET etc.) that can produce a CMOS invertor, there are no process node extensions and the design scales over a wide range of process node feature sizes. The CiFET is modelled to work in the 10 nano-meter feature size where a normal MOSFET amplifiers gain drops below one due to the dramatic lowering of the MOSFET's shunting resistance at these scales. Remember, as the feature size decreases, the MOSFET transconductance increases. A partial list of contemporary CMOS design books includes but not limited to, “Analysis and Design of Analog Integrated Circuits 5^{th} edition,” by Paul Gray et al.; “CMOS Analog Circuit Design Second Edition” by P. E. Allen et al., “The MOS Transistor 3^{rd} edition” by Y. Tsividis; “Microelectronic Circuits 7^{th} Edition” by Adel S. SEDRA et al., and “Charge-based MOS Transistor Modeling” by C. Enz and E. Vittoz.

One of the strengths of the CiFET family lies in the fact that the rich tapestry of analog MOS design is embraced by the CiFET approach. Industry standard analog design modelling software is used for analysis and circuit performance exploration. The professional level programs such as Cadence and HSpice is used unmodified by any extensions just as the process node on the silicon chip requires no extensions. The only requirement for the analysis software is that it must support an all-region simulation model such as EKV or BSIM level 6 models or higher. Specifically, these models merge one region of MOS operation say exponential inversion into the quadratic region where the square law dominates MOS performance in a smooth and differentially continuous fashion from one mode to the other mode. Piecewise models would produce model based abnormal results. In addition, the relative tolerance of the calculations must be set to very low levels in order to produce accurate results. Settings analysis parameters into the fempto-volts, fempto-amps and fempto-coulombs are also required. As modelling software develops capabilities into these ultra-low levels, the CiFETs model conformity will improve. Analog design modularity and performance claims support using the CiFET as a universally adaptable, ultra-wideband frequency response, ultra-low noise performance transparent amplification device. This combined with the fact that this analog performance may be integrated on the same silicon as adjacent digital CMOS structures means that chip internal signals between the two worlds do not have to be externalized, buffered and the interconnecting wires of the various chip modules need not be exposed to the wealth of external noises found in the world outside of the intimacy of the chip proper. The novelty of interaction with the external parasitics is minimized. The CiFET technology allows the analog sensor functions to be amplified, processed, digitized and passed onto adjacent digital processing is on the same chip. With CiFETs one is able to design a multifunction chip containing all the system components analog to digital and finally to the production of a data stream that is passed onto other system downstream and do it in an achievable design fashion and with an economical budget.

In addition to the iPort current injection signal modulation ports, there exists yet one more way to effect drain current modulation and therefore the signal output voltage of the CiFET. Often all the gates of the CiFET structure are connected together, and are connected to the mid-point bias potential call voltage common mode V_{cm}, however yet another signal may be superimposed on this mid-point bias common mode voltage. This signal source “sees” the high input impedance of a MOSFET gate with considerations of the V_{cm} impedance kept in mind. Small signal modulation from the CiFET gates will also be reflected in the modulation of the CiFET channel current and in the end in the CiFET amplified voltage output. This brings to three inputs that can simultaneously modulate the output voltage of a single CiFET. To accomplish the same function would require several operational amplifiers and external components, even more if one needed to match the input impedance requirements of a driving signal source. The CiFET offers a compact solution to many tricky sensors interface, low noise and wide bandwidth sensing problems.

When two CiFETs structures are paired and a Norton or Thevenin signal source is connected between the NiPorts of this pair of CiFETs, a differential sensor is produced. In this configuration the sensor current flows into one iPort and is drawn from the other connected iPort. These small current actions produce respective plus and minus swings on their respective CiFET outputs producing a differential output as well as sensing through a differential input.

As an example of dual CiFET trans-impedance amplifier (or TIA) use, please refer to the Whetstone bridge circuit presented in FIG. 4d. In this illustration, a four-terminal bridge 400 is presented, drive (or i Tset) 42 is applied between the top and bottom nodes. This drive 42 can be either a voltage or a current source. If the elements in the branches are matched the current down each leg will be equal and therefore the voltage at the undriven nodes will be equal. If, however, the elements are not symmetrically equal the arms will be imbalanced and the potential at the midpoint of the arms will not be equal. Each midpoint arm is connected to the NiPort 301a and 301b of a CiFETs 300a and 300b. This imbalance will cause unequal currents to flow into the respective NiPorts 301a and 301b. Current at NiPorts 301a and 301b determine that CiFETs output voltage 303a and 303b. If the current at NiPorts 301a and 301b is unequal the output voltage will be unequal, and the imbalance in the bridge 400 will be detected. Normally this detection would require a differential voltage amplifier. With CiFETs such a detector can be developed with a high input impedance with respect to the bridges impedances Z1 41a; Z2 41b; Z3 41c and Z4 41d, or it can be designed to be a differential current sensor. The specific design choice is made based on the specifics of the problem to be solved.

FIG. 5a illustrates an example of a differential trans-impedance amplifier (dCiTIA) 710. The circuit 710 consists of two appropriately-ratioed CiFET building blocks (iFET ratio of each of NiFETs and PiFETs are appropriately configured), including first CiFET 300f, second CiFET 300g, arranged to allow current inputs through PiPorts 32f and 32g and NiPorts 31f and 31g of the CiFETs 300f and 300g, while the first CiFET 300f output +Vₒᵤₜ 96a and the second CiFET 300g for −Vₒᵤₜ 96b, and generates V_{cm} or common mode voltage 97a/97b.

FIG. 5b shows a symbol diagram 710′ of dCiTIA 710 shown in FIG. 5a.

In FIG. 5c, a circuit using the CiFETs is presented that would be difficult to implement with operational amplifier based designs. This CiFET-based circuit 500 uses the ultra-high common mode rejection delivered by the differential CiFET or dCiTIA amplifier 710c configuration. The dCiTIA amplifier configuration that was used in the Wheatstone bridge (as shown in FIG. 4d) is now configured with several external resistors as shown. A RF antenna source 56 introduces the sensed signal to one of the connected differential input N or PiPorts. In this embodiment, an NiPort connection is shown. The antenna has a designed output impedance, usually around 50 ohms. That value of antenna impedance 54 is connected to the other NiPort. The two differential NiPorts are further connected with external resistors 52 and 53 of one half that value of the input impedance 54. In the simplest case, the junction of those resistors 52, 53, 54 and 55 are connected to ground, in the figure it is connected to another amplifier. Without the extra amplifier consider the case when the antenna signal injects current into its NiPort. In this case the injected current into the plus and minus differential NiPorts is not balanced and the CiFET will register that imbalance as an output voltage signal +Rcv and −Rcv. The antenna's signal will be amplified.

Now consider another case where the shown amplifier labelled PA 51 is connected to the junction of the half value resistors 52 and 53. It will drive current into the NiPort differential nodes of dCiTIA 710c. If the external resistances 52 and 53 are balanced and matched the PA amplifier will drive equal currents into these differential nodes. As the driven iPort currents are equal the dCiTIA amplifier 710c will not register the PA amplifiers 51 supplied current. The connected amplifier 51, however, will drive the connected antenna 56. The dCiTIA 710c will still amplify the unbalanced antenna signal current. The net result is that the CiFET will allow the antenna signal current to be registered while the antenna 56 is also, simultaneously transmitting the driven signal supplied by the external amplifier PA 51. In a further extension of this circuit one can replace the driving amplifier PA 56 with a feedback signal proportional to the dCiTIA output. In this case, the signal current and the current the antenna supplies are cancelled out by this feedback signal. The antenna 56 appears to be not connected to any loading impedance. However now with the antenna current effectively neutralized by the feedback signal, the feedback will now produce that cancelled antenna current as a NiPort imbalance to the other driven NiPort and once again the dCiTIA 710c will amplify the antenna's signal with the antenna looking like it is not connected to any circuit.

1. An apparatus comprising:
a. a complementary pair of a N-type current field-effect transistor (NiFET) and a P-type current field-effect transistor (PiFET), each of NiFET and PiFET comprises a source terminal, a drain terminal, a gate terminal, and a diffusion terminal of a corresponding conductivity type of said each of said PiFET and said NiFET, defining a source channel with a width and a length between said source terminal and said diffusion terminal, and a drain channel with a width and a length between said drain terminal and said diffusion terminal, said diffusion terminal causes changes in said diffused charge density throughout said source and drain channels, and said gate terminal is capacitively coupled to said source channel and said drain channel;
b. said gate terminal of said PiFET and said gate terminal of said NiFET are connected together to form a common gate terminal for referring to a common mode voltage, and said drain terminals of said NiFET and said PiFET are connected together to form an output; and
c. said diffusion terminal and said source terminal of one of said NiFET or PiFET are connected in series with a signal source having a source impedance;
wherein said source channel of said one of said NiFET and said PiFET having an input impedance for matching with said source impedance, said input impedance is adjusting by a ratio of said width to said length of said source channel over said width to said length of said drain channel of said one of said PiFET and said NiFET.

2. The apparatus as recited in claim 1, wherein said input impedance is further adjusted by a value of a supply power voltage.

3. The apparatus as recited in claim 2, wherein said ratio is adjusted to have said matching input impedance to be a low value for allowing to measure a short circuit current.

4. The apparatus as recited in claim 2, wherein said ratio is adjusted to have said matching input impedance to be a high value for allowing to measure a voltage source.

5. A transimpedance amplifier comprising:
a. a complementary pair of a N-type current field-effect transistor (NiFET) and a P-type current field-effect transistor (PiFET), each of NiFET and PiFET comprises a source terminal, a drain terminal, a gate terminal, and a diffusion terminal of a corresponding conductivity type of said each of said PiFET and said NiFET, defining a source channel with a width and a length between said source terminal and said diffusion terminal, and a drain channel with a width and a length between said drain terminal and said diffusion terminal, said diffusion terminal causes changes in said diffused charge density throughout said source and drain channels, and said gate terminal is capacitively coupled to said source channel and said drain channel;
b. said gate terminal of said PiFET and said gate terminal of said NiFET are connected together to form a common gate terminal, and said drain terminals of said NiFET and said PiFET are connected together to form an output; and
c. said diffusion terminal of said NiFET and said diffusion terminal of said PiFET for receiving input current;
wherein each of said source channel of said NiFET and said source channel of said PiFET having an input impedance for matching with said source impedance, and said common gate terminal having a high-input impedance;
wherein said input impedance for said NiFET is adjusting by a ratio of said width to said length of said source channel over said width to said length of said drain channel of said NiFET; and
wherein said input impedance for said PiFET is adjusting by a ratio of said width to said length of said source channel over said width to said length of said drain channel of said PiFET.

6. A differential transimpedance amplifier, comprising:
a. a first complementary pair of a first n-type current field-effect transistor (NiFET) and a first p-type current field-effect transistor (PiFET);
b. a second complementary pair of a second NiFET and a second PiFET;
wherein each of said NiFETs and PiFETs comprises:
i. a source terminal, a drain terminal, a gate terminal, and a diffusion terminal of a corresponding conductivity type of said each of said PiFET and NiFET, defining a source channel between said source terminal and said diffusion terminal, and a drain channel between said drain terminal and said diffusion terminal, said diffusion terminal causes changes in said diffused charge density throughout said source and drain channels, and said gate terminal is capacitively coupled to said source channel and said drain channel;
ii. wherein said gate terminal of said PiFET and said gate terminal of said NiFET are connected together to form a common gate terminal for said each complimentary pair, said source terminal of said NiFET of said each pair is connected to negative power supply and said source terminal of said PiFET of said each pair is connected to positive power supply, and drain terminals of said NiFET and said PiFET are connected together to form an output; and
iii. wherein said common gate of said first complimentary pair and said common gate of said second complementary pair are connected with said output of said second complementary pair to for generating an output voltage swings about a common mode voltage;
said diffusion terminal of said first NiFET receives a positive input current and said diffusion terminal of said second NiFET receives a negative input current; and
said output of said first complementary pair forms a positive voltage output and said output of said second complementary pair forms a negative voltage output of said trans-impedance amplifier.
